(19) United States
(12) Patent Application Publication
(10) Pub. No.: US 2026/0362708 A1
(43) Pub. Date: Nov. 12, 2026

(54) THREE-TERMINAL MEMORY ELEMENT INTEGRATED WITH A STAGGERED STACKED FET DEVICE

(71) Applicant: International Business Machines Corporation, Armonk, NY (US)

(72) Inventors: Debarghya Sarkar, Latham, NY (US); Ching-Tzu Chen, Ossining, NY (US); Utkarsh Bajpai, Suffern, NY (US); Henry K. Utomo, Ridgefield, CT (US)

(21) Appl. No.: 19/176,347

(22) Filed: Apr. 11, 2025

(51) Int. Cl. H10B 61/00

(52) U.S. Cl. CPC H10B 61/20

(57) ABSTRACT

A semiconductor device is provided that includes a non-volatile memory cell including a three-terminal memory element integrated with two transistors stacked in a staggered configuration in which the three-terminal memory element is positioned on the backside of both field effect transistors and vertically located directly beneath one of the transistors.

### BACKGROUND

The present application relates to semiconductor technology, and more particularly to a semiconductor device including a three-terminal memory element integrated with a staggered stacked field effect transistor (FET) device.

Magnetoresistive random access memory (MRAM) is a non-volatile random access memory technology in which data is stored by magnetic storage elements. These elements are typically formed from two ferromagnetic layers, each of which can hold a magnetization, separated by a thin dielectric layer (i.e., a tunnel barrier layer). One of the two layers (i.e., the magnetic reference or pinned layer) is a magnet whose magnetic moment direction is set to a particular direction; the other layer's (i.e., the magnetic free layer's) magnetization can be changed in at least two different directions, representing different digital states such as 0 and 1 for memory applications. In MRAMs, such elements may be referred to as a magnetic tunnel junction (MTJ) structure. In a typical MTJ structure, the magnetization of the magnetic reference layer is fixed in one direction (say pointing up), while the direction of the magnetic free layer can be “switched” by some external forces, such as a magnetic field or a spin-torque generating charge current. A smaller current (of either polarity) can be used to read the resistance of the device, which depends on the relative orientations of the magnetizations of the magnetic free layer and the magnetic reference layer. The resistance is typically higher when the magnetizations are anti-parallel, and lower when they are parallel.

One type of MRAM device that can use a MTJ structure is a spin-transfer torque (STT) MRAM. STT MRAM has the advantages of lower power consumption and better scalability over conventional MRAM which uses magnetic fields to flip the active elements. In STT MRAM, spin-transfer torque is used to flip (switch) the orientation of the magnetic free layer. For an STT MRAM device, a current passing through the MTJ structure is used to switch, or “write” the bit-state of the MTJ memory element. A current passing down through the MTJ structure makes the magnetic free layer parallel to the magnetic reference layer, while a current passed up through the MTJ structure makes the magnetic free layer anti-parallel to the magnetic reference layer.

Another type of MRAM device that can use a MTJ structure is a spin-orbit torque (SOT) MRAM device. SOT memory devices do not require passing of high current through the MTJ structure during the write operation, which is done by a current flowing through a SOT channel layer. SOT MRAM devices are actively being considered as a beyond STT MRAM option for reducing write current and eliminating read disturb.

### SUMMARY

A semiconductor device is provided that includes a three-terminal memory element integrated with two transistors stacked in a staggered configuration in which the three-terminal memory element is positioned on the backside of both transistors and vertically located directly beneath one of the transistors. Collectively, the three-terminal memory element and the two transistors stacked in a staggered configuration provide a non-volatile memory cell of the present application

In one embodiment of the present application, the semiconductor device includes a field effect transistor device having a frontside and a backside and including a top transistor stacked in a staggered configuration above a bottom transistor, where both the bottom transistor and the top transistor are located on the frontside of the field effect transistor device; and a three-terminal memory element integrated with, and present on backside of, the field effect transistor device, where the three-terminal memory element is positioned vertically and directly beneath one of the top transistor or the bottom transistor.

In another embodiment of the present application, the semiconductor device includes a field effect transistor device having a frontside and a backside and including a top transistor stacked in a staggered configuration above a bottom transistor, where both the bottom transistor and the top transistor are located on the frontside of the field effect transistor device; and a three-terminal memory element integrated with, and present on backside of, the field effect transistor device, where the three-terminal memory element is positioned vertically and directly beneath the top transistor, and the three-terminal memory element has an uppermost layer electrically connected to a top transistor first source/drain region and a bottommost layer electrically connected to both a bottom transistor first source/drain region and a backside back-end-of-line structure that is located beneath the three-terminal memory element, where the top transistor includes a top transistor second source/drain region electrically connected to both a bottom transistor second source/drain region and a frontside back-end-of-line structure that is positioned above the top transistor and where the bottom transistor includes a bottom transistor gate electrode electrically connected to the backside back-end-of-line structure and the top transistor includes a top transistor gate electrode electrically connected to the frontside back-end-of-line structure.

In a further embodiment of the present application, the semiconductor device includes a field effect transistor device having a frontside and a backside and including a top transistor stacked in a staggered configuration above a bottom transistor, where both the bottom transistor and the top transistor are located on the frontside of the field effect transistor device; and a three-terminal memory element integrated with, and present on backside of, the field effect transistor device, where the three-terminal memory element is positioned vertically and directly beneath the bottom transistor, and the three-terminal memory element has an uppermost layer electrically connected to a bottom transistor first source/drain region and a bottommost layer electrically connected to both a top transistor first source/drain region and a backside back-end-of-line structure that is located beneath the three-terminal memory element, where the top transistor includes a top transistor second source/drain region electrically connected to both a bottom transistor second source/drain and a frontside back-end-of-line (BEOL) structure that is positioned above the top transistor, and where the bottom transistor includes a bottom transistor gate electrode electrically connected to the backside BEOL structure and the top transistor includes a top transistor gate electrode electrically connected to the frontside back-end-of-line structure.

### BRIEF DESCRIPTION OF THE DRAWINGS

FIG. 1 is a top down view of a semiconductor device layout that can be used in the present application; the top down view includes five cuts, namely X1-X1, X2-X2, Y1-Y1, Y2-Y2 and Y3-Y3 that will be used throughout the present application to exemplify the semiconductor device of the present application.

FIGS. 2A, 2B, 2C, 2D and 2E are various views of a semiconductor device in accordance with an embodiment of the present application.

FIGS. 3A, 3B, 3C, 3D and 3E are various views of a semiconductor device in accordance with another embodiment of the present application.

FIGS. 4A, 4B, 4C, 4D and 4E are various views of a semiconductor device in accordance with yet another embodiment of the present application.

FIGS. 5A, 5B, 5C, 5D and 5E are various views of a semiconductor device in accordance with a yet further embodiment of the present application.

FIGS. 6A, 6B, 6C, 6D and 6E are various views of an initial structure including a bottom transistor located on a substrate that can be employed in accordance with an embodiment of the present application.

FIGS. 7A, 7B, 7C, 7D and 7E are various views of the initial structure shown in FIGS. 6A, 6B, 6C, 6D and 6E, respectively, after forming a top transistor above the bottom transistor in which the top transistor is staggered relative to the bottom transistor.

FIGS. 8A, 8B, 8C, 8D and 8E are various views of the exemplary structure shown in FIGS. 7A, 7B, 7C, 7D and 7E, respectively, after forming a frontside bottom source/drain contact structure contacting a bottom transistor second source/drain region.

FIGS. 9A, 9B, 9C, 9D and 9E are various views of the exemplary structure shown in FIGS. 8A, 8B, 8C, 8D and 8E, respectively, after forming frontside top contact structures including a frontside top gate contact structure in contact with a top transistor gate electrode of the top transistor, and a frontside top source/drain contact structure in contact with a second top source/drain region and with the frontside bottom source/drain contact structure.

FIGS. 10A, 10B, 10C, 10D and 10E are various views of the exemplary structure shown in FIGS. 9A, 9B, 9C, 9D and 9E, respectively, after forming a frontside back-end-of-line (BEOL) structure and bonding the same to a carrier wafer.

FIGS. 11A, 11B, 11C, 11D and 11E are various views of the exemplary structure shown in FIGS. 10A, 10B, 10C, 10D and 10E, respectively, after removing the substrate and replacing the same with a backside interlayer dielectric (ILD) layer.

FIGS. 12A, 12B, 12C, 12D and 12E are various views of the exemplary structure shown in FIGS. 11A, 11B, 11C, 11D and 11E, respectively, after forming a backside top source/drain contact structure contacting a top transistor first source/drain region.

FIGS. 13A, 13B, 13C, 13D and 13E are various views of the exemplary structure shown in FIGS. 12A, 12B, 12C, 12D and 12E, respectively, after forming a backside bottom source/drain contact structure in contact with a bottom transistor first source/drain region and a backside top source/drain extension contact structure in contact with the backside top source/drain contact structure.

FIGS. 14A, 14B, 14C, 14D and 14E are various views of the exemplary structure shown in FIGS. 13A, 13B, 13C, 13D and 13E, respectively, after forming a MTJ structure and a SOT channel layer.

FIGS. 15A, 15B, 15C, 15D and 15E are various views of the exemplary structure shown in FIGS. 14A, 14B, 14C, 14D and 14E, respectively, after forming additional backside ILD material.

FIGS. 16A, 16B, 16C, 16D and 16E are various views of the exemplary structure shown in FIGS. 15A, 15B, 15C, 15D and 15E, respectively, after forming a memory element contact structure in contact with the SOT channel layer and with the backside bottom source/drain contact structure that contacts the bottom transistor first source/drain region.

FIGS. 17A, 17B, 17C, 17D and 17E are various views of the exemplary structure shown in FIGS. 16A, 16B, 16C, 16D and 16E, respectively, after forming a backside bottom gate contact structure.

FIGS. 18A, 18B, 18C, 18D and 18E are various views of the exemplary structure shown in FIGS. 17A, 17B, 17C, 17D and 17E, respectively, after forming a backside BEOL structure.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

SOT MRAM (and other three-terminal memory elements) are actively being researched for their potential to outperform STT MRAM in reducing write current, improving switching time below 1 ns, and eliminating read disturb. However SOT MRAM requires two access transistors, one for performing a read operation and the other for performing a write operation. Thus, the cell size of the SOT MRAM is substantially larger than the STT MRAM which requires only one access transistor for both read and write To reduce cell size, it is known to integrate SOT MRAM devices on the frontside BEOL structure of I-shaped stacked nanosheet field effect transistors (FETs). To continue scaling, stacked nanosheet FETs with a staggered configuration and backside interconnects has emerged as a top device architecture candidate, e.g., for packing the highest density of semiconductor logic cells and largest effective width (W_{eff}) of a transistor channel within a given area. However, adopting stacked FETs with backside contacts and interconnects render it difficult to integrate SOT MRAM devices on the frontside due to the thermal constraints of MRAM devices—annealing of the backside contacts requires a temperature of greater than 800 °C, while the metal in the MRAM stack begin to diffuse significantly above 500 °C causing MRAM device degradation or complete breakdown. The present application solves this problem of MRAM stack metal diffusion by forming the MRAM stack on the backside of a field effect transistor device containing two transistors that are stacked in a staggered configuration. Throughout the present application, the term “staggered configuration” denotes that the top transistor is not vertically aligned directly above the bottom transistor. In a stacked staggered configuration, there is some lateral offset of the top transistor from the bottom transistor. The integration of the SOT MRAM element (and other like three-terminal memory elements) on the backside of the staggered stacked transistors is performed after all high thermal budget steps (such as annealing) have been formed.

In the present application, a transistor (or FET) includes a source region, a drain region, a semiconductor channel region located between the source region and the drain region, and a gate structure located above the semiconductor channel region. Collectively, the source region and the drain region can be referred to as a source/drain region. A transistor includes a first source/drain region located on one side of a semiconductor channel region and a second source/drain region located on a second side of the semiconductor channel region. As used herein, a “source/drain” region can be a source region or a drain region depending on subsequent wiring and application of voltages during operation of the transistor. In the embodiments described in the present application, each transistor (i.e., bottom transistor and top transistor) is a nanosheet transistor. A nanosheet transistor is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. The gate structure includes a gate dielectric and a gate electrode. The gate structure wraps around each of the spaced apart semiconductor channel material nanosheets. Nanosheet transistors provide considerable scaling with high drive current capability. Nanosheet transistors provide a larger drive current for a given footprint compared to finFET technology. Although nanosheet transistors are described in the embodiments of the present application, the present application is not limited to nanosheet transistors. Instead, the present application can be used for finFETs, nanowire transistors, planar transistor, fork sheet transistors, or any combination of such transistors including nanosheet transistors that can be stacked one on top the other in a staggered configuration.

In the present application, the semiconductor device includes a frontside and a backside. The frontside includes a side of the device that includes the staggered stacked transistors, frontside contact structures, and a frontside BEOL structure. The backside of the semiconductor device is the side of the device that is opposite the frontside and is located beneath the stacked staggered FETs. The backside includes backside contact structures, a backside BEOL structure, and a three-terminal memory element, such as for example, an SOT MRAM or an electrochemical random access memory (ECRAM). The backside BEOL structure can be a backside power distribution network that is capable of delivering power to the stacked transistors through the backside of the semiconductor device. Alternatively, the backside BEOL structure can be used for backside signal routing or both.

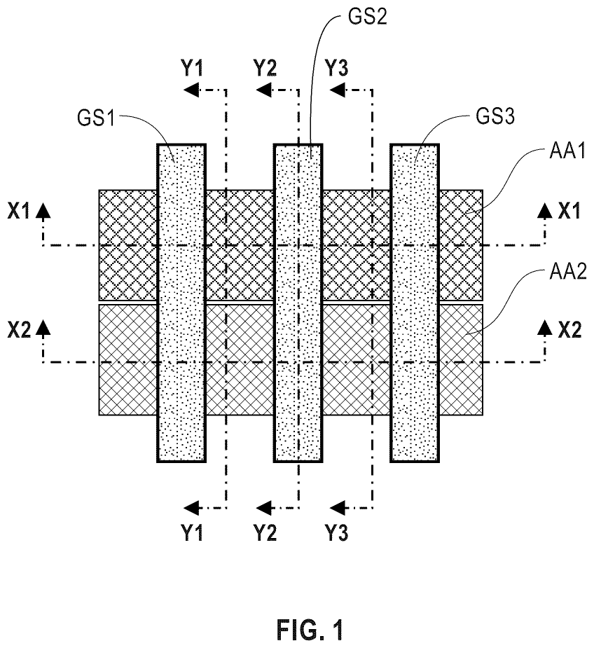

Before discussing the present application in further detail, reference is made to FIG. 1 which is a top down view of a semiconductor device layout that can be used in the present application. The device layout illustrated in FIG. 1 will be used to further describe the semiconductor device of the present application. The top down view illustrated in FIG. 1 includes a bottom device active area, AA1, and a top device active area, AA2. The bottom device active area, AA1, is an area in which at least one bottom transistor will be located, and the top device area, AA2, is an area in which at least one top FET will be located. In the present application, top device area, AA2, is located above bottom device area, AA1. The device layout of FIG. 1 also illustrates three top transistor gate structures in the top device active area, AA2, namely first top transistor gate structure, GS1, second top transistor gate structure GS2, and third top transistor gate structure G3; bottom transistor gate structures are not shown but would be present in a staggered configuration in the bottom device active area, AA1. Although three top transistor gate structures are described and illustrated in the device layout of FIG. 1, the present application is not limited to that number of top transistor gate structures. Instead, the present application works when a single top transistor gate structure, two top transistor gate structures or more than three top transistor gate structures are present. The number of bottom transistor gate structures can vary as long as at least one bottom transistor gate structure is present in the bottom device active area, AA1. Each gate structure (top or bottom) is oriented parallel to each other and perpendicular to the bottom device active area, AA1, and the top device active area, AA2.

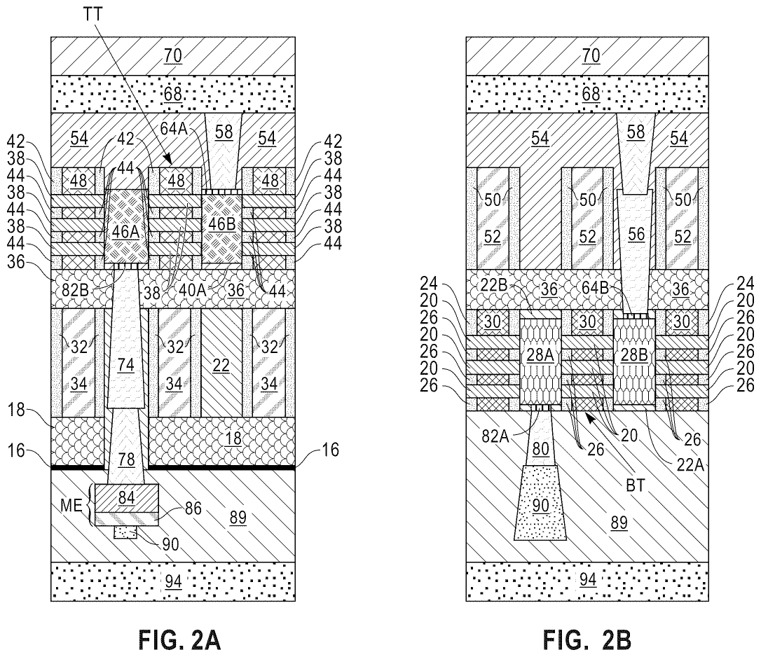

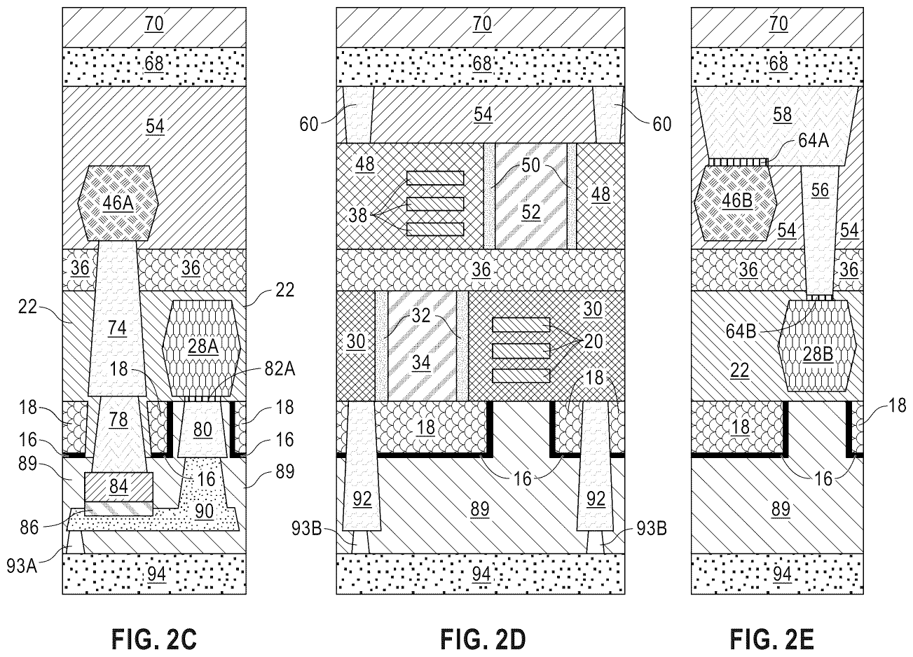

The device layout illustrated in FIG. 1 also includes five cuts, namely X1-X1, X2-X2, Y1-Y1, Y2-Y2 and Y3-Y3 that will be used throughout the present application to exemplify the semiconductor device of the present application. In the present application, X1-X1 is a cross sectional view that runs in a length-wise direction through a portion of the top device active area, AA2 and an underlying portion of a bottom device region, AA1; X2-X2 is a cross sectional view that runs in a length-wise direction through a portion of the bottom device active area, AA1 and an overlaying portion of a top device region; Y1-Y1 is a cross sectional view that runs in a length-wise direction in area (a first top source/drain area) that is located on a first side of the second top transistor gate structure, GS2; Y2-Y2 is a cross sectional view that runs in a length-wise direction through a portion of the second top transistor gate structure, GS2; and Y3-Y3 is a cross sectional view that runs in a length-wise direction in area (a second top source/drain area) that is located on a second side of the second top transistor gate structure, GS2, the second side being opposite to the first side. FIGS. 2A, 2B, 2C, 2D and 2E are various views of a semiconductor device in accordance with an embodiment of the present application.

In the drawings of the present applications, each of FIGS. 2A, 3A, 4A, 5A, 6A, 7A, 8A, 9A, 10A, 11A, 12A, 13A, 14A, 15A, 16A, 17A and 18A is a cross sectional view through cut X1-X1; each of FIGS. 2B, 3B, 4B, 5B, 6B, 7B, 8B, 9B, 10B, 11B, 12B, 13B, 14B, 15B, 16B, 17B and 18B is a cross sectional view through cut X2-X2; each of FIGS. 2C, 3C, 4C, 5C, 6C, 7C, 8C, 9C, 10C, 11C, 12C, 13C, 14C, 15C, 16C, 17C and 18C is a cross sectional view through cut Y1-Y1; each of FIGS. 2D, 3D, 4D, 5D, 6D, 7D, 8D, 9D, 10D, 11D, 12D, 13D, 14D, 15D, 16D, 17D and 18D is a cross sectional view through cut Y2-Y2; and each of FIGS. 2E, 3E, 4E, 5E, 6E, 7E, 8E, 9E, 10E, 11E, 12E, 13E, 14E, 15E, 16E, 17E and 18E is a cross sectional view through cut Y3-Y3.

The present application provides a semiconductor device including a field effect transistor device having a frontside and a backside and including a top transistor, TT, stacked in a staggered configuration above a bottom transistor BT, where both the bottom transistor, BT and the top transistor, TT, are located on the frontside of the field effect transistor device. The semiconductor device of the present application also includes a three-terminal memory element, ME, integrated with, and present on the backside of, the field effect transistor device. In the present application, the three-terminal memory element, ME, is positioned vertically and directly beneath one of the top transistor, TT, or the bottom transistor, BT. Such a semiconductor device is illustrated in FIGS. 2A-2E, FIGS. 3A-3E, FIGS. 4A-4E and FIGS. 5A-5E. The semiconductor device of the present application has a high density of semiconductor logic cells with a large W_{eff} within a given area that boosts FET device performance by increasing drive current.

Moreover, the three-terminal memory element, ME, in the semiconductor device of the present application is formed on the backside of the field effect transistor device after forming backside contact structures (including metal silicide layers) that require high temperature anneals. Since the three-terminal memory element, ME, is formed after backside contact structure formation, the degradation or complete breakdown of the three-terminal memory element due to any such high-temperature anneals can be avoided The semiconductor device of the present application is fully compatible with backside BEOL structures that are designed to deliver power to the top and bottom transistors of the field effect transistor device including the stacked and staggered stacked transistors.

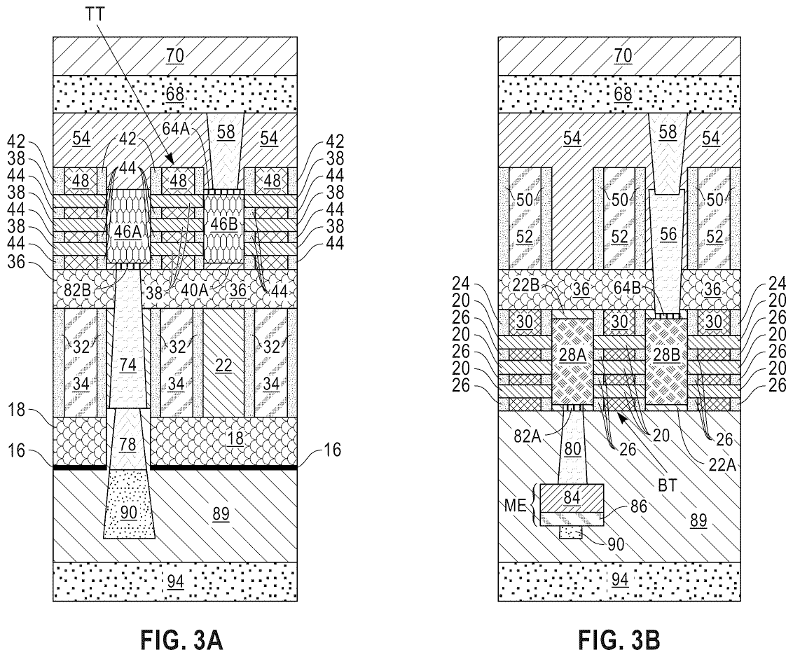

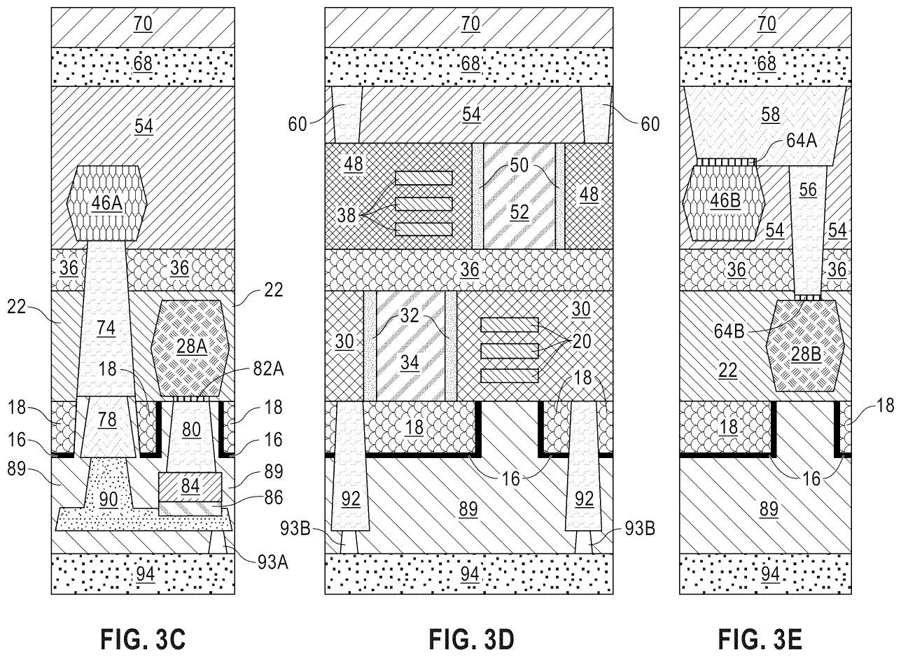

In some embodiments, and as is illustrated, for example, FIGS. 2A-2E, and FIGS. 3A-3E, the three-terminal memory element, ME, includes a spin-orbit torque magnetoresistive random access memory (SOT MRAM). The SOT RAM includes magnetic tunnel junction structure 84 located directly on spin-orbit torque channel layer 86. A SOT MRAM provides reduced write current and improved switching time below 1 ns and eliminates read disturb compared with STT-MRAMs.

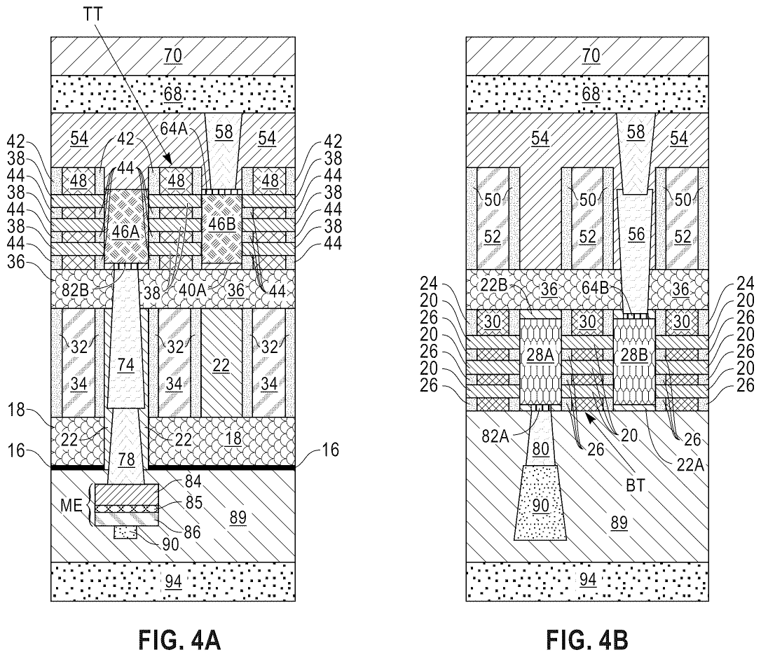

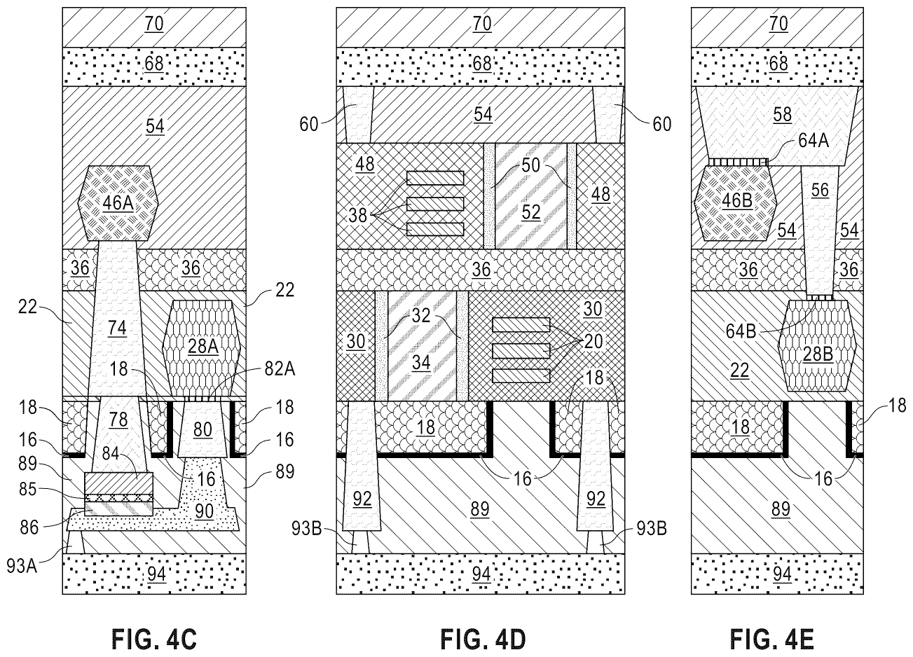

In some embodiments, and as is illustrated, for example, FIGS. 4A-4E , the three-terminal memory element, ME, includes a spin-orbit torque magnetoresistive random access memory including magnetic oxide layer 85 positioned between magnetic tunnel junction (MTJ) structure 84 and spin-orbit torque channel layer 86. The presence of the magnetic oxide layer 85 between the MTJ structure 84 and spin-orbit torque channel layer 86 can significantly suppress or completely eliminate current shunting, thereby significantly reducing the switching current density as compared to the SOT MRAM illustrated in FIGS. 2A-2E, and FIGS. 3A-E.

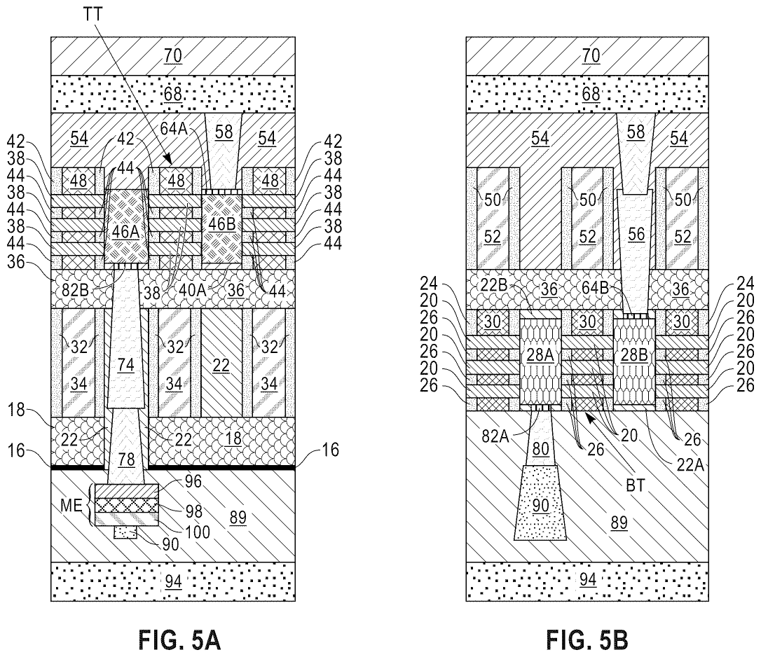

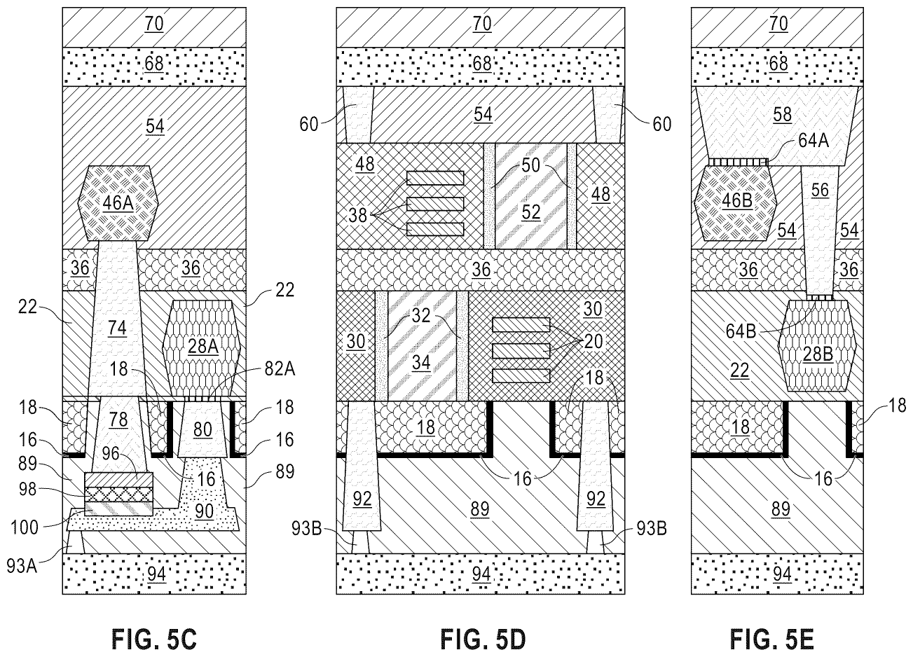

In some embodiments, and as is illustrated, for example, in FIGS. 5A-5E, the three-terminal memory element, ME, includes an electrochemical random access memory (ECRAM). The ECRAM includes solid-state electrolyte layer 98 positioned between gate layer 96 and channel layer 100. ECRAM devices provide uniform and deterministic control of the channel conductance by electrochemical insertion and extraction of ions into the channel, forming programmable analog resistors as artificial synapses in artificial neural network applications.

In some embodiments, and as is illustrated in FIGS. 2A-5E, backside contact structures (e.g., backside top source/drain contact structure 74, backside top source/drain extension contact structure 78, backside bottom source/drain contact structure 80, and backside bottom gate contact structure 92) are present. The backside contact structures electrically connect the three-terminal memory element, ME, to the top transistor, TT, and bottom transistor, BT, of the field effect transistor device. For example, backside top source/drain contact structure 74 and backside top source/drain extension contact structure 78 can be used to electrically connect the three-terminal memory element, ME, to a source/drain region of the top transistor. In the some embodiments, at least one of the backside contact structures include a metal silicide layer (e.g., third metal silicide layer 82B and/or fourth metal silicide layer 82A) in direct contact with a source/drain region (i.e., top transistor first source/drain region 48A or bottom transistor first source/drain region 28A) of either the top transistor, TT, or the bottom transistor, BT. The presence of the metal silicide layer helps to reduce the contact resistance of the backside contact structure.

In some embodiments, and as is illustrated in FIGS. 2A, 2B, 2C, 2D and 2E, FIGS. 4A, 4B, 4C, 4D and 4E and FIGS. 5A, 5B, 5C, 5D and 5E, the three-terminal memory element, ME, is positioned vertically and directly beneath the top transistor. TT. In such an embodiment, the three-terminal memory element, ME, has an uppermost layer (i.e., an upper layer of the either the magnetic tunnel junction structure 84 or the gate layer 96) electrically connected to a top transistor first source/drain region 46A and a bottommost layer (e.g., SOT channel layer 86 or channel layer 100) electrically connected to both a bottom transistor first source/drain region 28A and a backside back-end-of-line structure 94 that is located beneath the three-terminal memory element, ME, where the top transistor, TT, includes a top transistor second source/drain region 46B electrically connected to both a bottom transistor second source/drain region 28B and a frontside back-end-of-line structure 68 that is positioned above the top transistor, TT. This embodiment illustrates the electrically connection of the three-terminal memory element to the field effect transistor device that can be used in instances in which the memory element is positioned vertically and directly beneath the top transistor, TT.

In such embodiments, the bottom transistor, BT, includes a bottom transistor gate electrode (within bottom transistor gate structure 30) electrically connected to the backside back-end-of-line structure 94 and the top transistor, TT, includes a top transistor gate electrode (within top transistor gate structure 48) electrically connected to the frontside back-end-of-line structure 68. This provides further electrically connection for the embodiment in which the memory element is positioned vertically and directly beneath the top transistor, TT.

In some embodiments, and as is illustrated in FIGS. 3A-3E, the three-terminal memory element, ME. is positioned vertically and directly beneath the bottom transistor, BT, and the three-terminal memory element has an uppermost layer electrically connected to a bottom transistor first source/drain region 28A and a bottommost layer electrically connected to both a top transistor first source/drain region 46A and a backside back-end-of-line structure 94 that is located beneath the three-terminal memory element, ME, where the top transistor, TT, includes a top transistor second source/drain region 46B electrically connected to both a bottom transistor second source/drain region 28B and a frontside back-end-of-line structure 68 that is positioned above the top transistor, TT. This embodiment illustrates the electrically connection of the three-terminal memory element to the field effect transistor device that can be used in instances in which the memory element is positioned vertically and directly beneath the bottom transistor, BT.

In such embodiments, the bottom transistor, BT, includes a bottom transistor gate electrode (within bottom transistor gate structure 30) electrically connected to the backside back-end-of-line structure 94 and the top transistor, TT, includes a top transistor gate electrode (within top transistor gate structure 48) electrically connected to the frontside back-end-of-line structure 68. This provides further electrically connection for the embodiment in which the memory element is positioned vertically and directly beneath the bottom transistor, BT.

In some embodiments, the top transistor and the bottom transistor are of a same polarity (i.e., both transistors are an n-type FET or a p-type FET).

In some embodiments, the top transistor and the bottom transistor are of a different polarity (i.e., the top transistor is an n-type FET and the bottom transistor is a p-type FET, or the top transistor is a p-type FET and the bottom transistor is an n-type FET).

In some embodiments, and as is illustrated in FIGS. 2A-5E, the semiconductor device further includes a bonding dielectric layer 36 separating the top transistor, TT, from the bottom transistor, BT. The presence of the bonding dielectric layer 36 electrically isolates the top transistor, TT, from the bottom transistor, BT.

In some embodiments, and as illustrated in FIGS. FIGS. 2A, 2B, 2C, 2D and 2E, FIGS. 4A, 4B, 4C, 4D and 4E and FIGS. 5A, 5B, 5C, 5D and 5E, a semiconductor device is provided that includes a field effect transistor device having a frontside and a backside and including a top transistor, TT, stacked in a staggered configuration above a bottom transistor, BT, where both the bottom transistor, BT, and the top transistor, TT, are located on the frontside of the field effect transistor device; and a three-terminal memory element, ME, integrated with, and present on the backside of, the field effect transistor device, where the three-terminal memory element, ME, is positioned vertically and directly beneath the top transistor, TT, and the three-terminal memory element, ME, has an uppermost layer electrically connected to a top transistor first source/drain region 46A and a bottommost layer electrically connected to both a bottom transistor first source/drain region 28A and a backside back-end-of-line structure 94 that is located beneath the three-terminal memory element, ME, where the top transistor, TT, includes a top transistor second source/drain region 46B electrically connected to both a bottom transistor second source/drain region 28B and a frontside back-end-of-line structure 68 that is positioned above the top transistor, TT, and where the bottom transistor, BT, includes a bottom transistor gate electrode (within bottom transistor gate structure 30) electrically connected to the backside back-end-of-line structure 94 and the top transistor, TT, includes a top transistor gate electrode (within the top transistor gate structure 48) electrically connected to the frontside back-end-of-line structure 68. The semiconductor device of this embodiment has a high density and a large W_{eff} within a given area. This embodiment illustrates the electrically connection of the three-terminal memory element to the field effect transistor device that can be used in instances in which the memory element is positioned vertically and directly beneath the top transistor, TT.

In some embodiments, the three-terminal memory element, ME, the three-terminal memory element, ME, includes a spin-orbit torque magnetoresistive random access memory (SOT MRAM), as defined above. A SOT MRAM provides reduced write current and improved switching time below 1 ns and eliminates read disturb compared with STT-MRAMs.

In some embodiments, the three-terminal memory element, ME, includes a spin-orbit torque magnetoresistive random access memory including magnetic oxide layer 85 positioned between magnetic tunnel junction structure 84 and spin-orbit torque channel layer 86. The presence of the magnetic oxide layer 85 between magnetic tunnel junction structure 84 and spin-orbit torque channel layer 86 significantly suppress or completely eliminates current shunting, thereby significantly reducing the switching current density as compared to the SOT MRAM illustrated in FIGS. 2A, 2B, 2C, 2D and 2E, and FIGS. 3A, 3B, 3C, 3D and 3E.

In some embodiments, and as is illustrated, for example, in FIGS. 5A, 5B, 5C, 5D and 5E, the three-terminal memory element, ME, includes an electrochemical random access memory (ECRAM), as defined above.

In some embodiments, and as illustrated in FIGS. 3A-3E, the semiconductor device includes a field effect transistor device having a frontside and a backside and including a top transistor, TT, stacked in a staggered configuration above a bottom transistor, BT, where both the bottom transistor, BT, and the top transistor, TT, are located on the frontside of the field effect transistor device; and a three-terminal memory element, ME, integrated with, and present on the backside of, the field effect transistor device, where the three-terminal memory element ME, is positioned vertically and directly beneath the bottom transistor, BT, and the three-terminal memory element ME, has an uppermost layer electrically connected to a bottom transistor first source/drain region 28A and a bottommost layer electrically connected to both a top transistor first source/drain region 46A and a backside back-end-of-line structure 94 that is located beneath the three-terminal memory element, ME, where the top transistor, TT, includes a top transistor second source/drain region 46B electrically connected to both a bottom transistor second source/drain region 28B and a frontside back-end-of-line structure 68 that is positioned above the top transistor, TT, and where the bottom transistor, BT includers a bottom transistor gate electrode (within bottom transistor gate structure 30) electrically connected to the backside back-end-of-line structure 94 and the top transistor, TT, includes a top transistor gate electrode (within the top transistor gate structure 48) electrically connected to the frontside back-end-of-line structure 68. The semiconductor device of this embodiment has a high density and a large Weff within a given area. This embodiment illustrates the electrically connection of the three-terminal memory element to the field effect transistor device that can be used in instances in which the memory element is positioned vertically and directly beneath the bottom transistor, BT

In some embodiments, the three-terminal memory element, ME, includes a spin-orbit torque magnetoresistive random access memory (SOT MRAM), as defined above. A SOT MRAM provides reduced write current and improved switching time below 1 ns and eliminates read disturb compared with STT-MRAMs.

In some embodiments, the three-terminal memory element, ME, includes a spin-orbit torque magnetoresistive random access memory including magnetic oxide layer 85 positioned between magnetic tunnel junction structure 84 and spin-orbit torque channel layer 86. The presence of the magnetic oxide layer 85 between magnetic tunnel junction structure 84 and spin-orbit memory channel layer 86 significantly suppress or completely eliminates current shunting, thereby significantly reducing the switching current density as compared to the SOT MRAM illustrated in FIGS. 2A, 2B, 2C, 2D and 2E, and FIGS. 3A, 3B, 3C, 3D and 3E.

In some embodiments, and as is illustrated, for example, in FIGS. 5A-5E, the three-terminal memory element, ME, includes an electrochemical random access memory (ECRAM), as defined above.

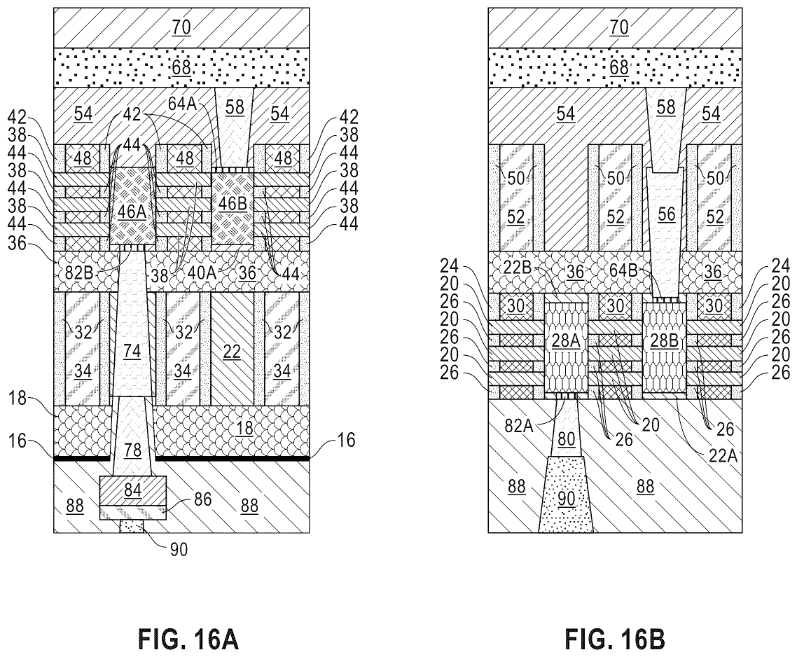

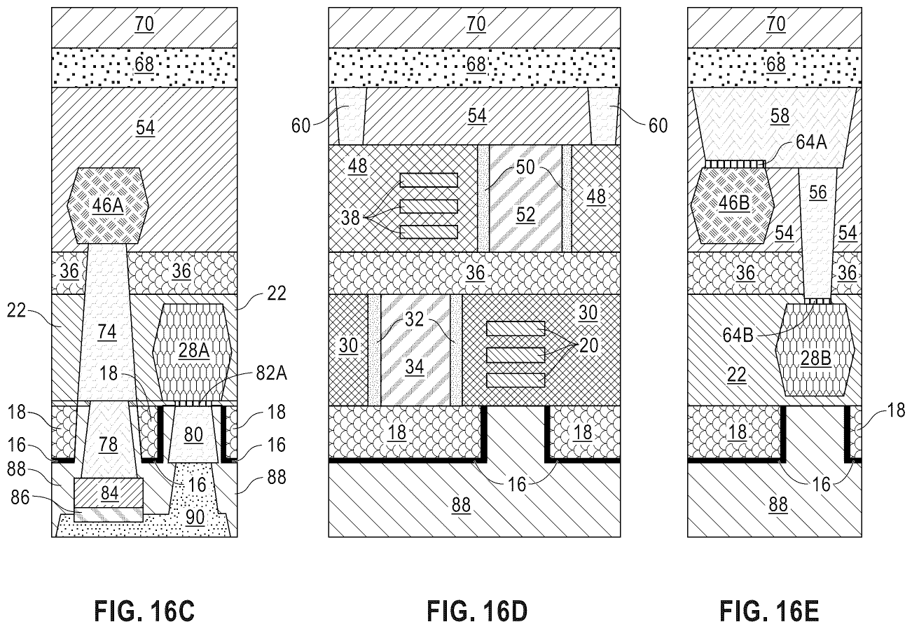

It should be noted that while FIGS. 5A-5E specifically illustrates the ECRAM located vertically and directly beneath the top transistor, TT, the present application contemplates embodiments in which the ECRAM is located vertically and directly beneath the bottom transistor, BT. It is also noted that the other elements illustrated in FIGS. 2A-5E that are not specifically mentioned above will become apparent by the description regarding the basic processing steps illustrated in FIGS. 16A-18E.

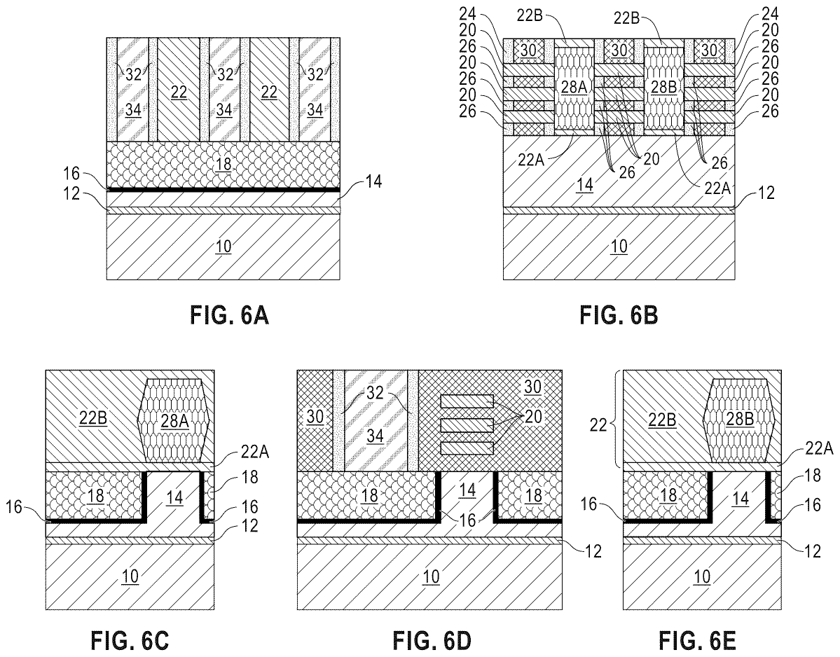

Reference is now made to FIGS. 6A-18E which illustrates basic processing steps that can be used in forming the exemplary semiconductor device illustrated in FIGS. 2A-2E. It is noted that modifications to the basic processing steps illustrated in FIGS. 6A-18E can be used in forming the semiconductor devices illustrated in FIGS. 3A-3E, FIGS. 4A-4E and FIGS. 5A-5E. The modifications to the basic processing steps needed to form the semiconductor devices illustrated in FIGS. 3A-3E, FIGS. 4A-4E and FIGS. 5A-5E are well within the knowledge of one skilled in the art.

The process begins by providing an initial structure as is illustrated in FIGS. 6A-6E. The initial structure includes a bottom transistor located on a substrate. In the embodiment illustrated in the present application, three bottom transistors are illustrated by way of one example. Each bottom transistor is a nanosheet transistor including a bottom transistor gate structure 30 wrapped around a vertical stack of spaced apart bottom semiconductor channel material nanosheets (each vertical stack of spaced apart bottom semiconductor channel material nanosheets includes a plurality of bottom semiconductor channel material nanosheets 20). Each bottom transistor further includes a bottom transistor first source/drain region 28A located on one side of the vertical stack of spaced apart bottom semiconductor channel material nanosheets and a bottom transistor second source/drain region 28B located on a second side of the vertical stack of spaced apart bottom semiconductor channel material nanosheets. In FIG. 6B, the other source/drain region for the bottom transistors on the left hand side and the right hand side are not shown in the cross sectional view. Each bottom transistor also includes a bottom transistor gate spacer 24 and bottom transistor inner spacers 26. The bottom transistor inner spacers 26 are used as supporting elements for the vertical stack of spaced apart bottom semiconductor channel material nanosheets. The inner spacer improves the device performance by reducing the parasitic capacitance between the gate and the source/drain regions. The bottom transistor gate spacer 24 is present along a sidewall of the bottom transistor gate structure 30. Each bottom transistor can be formed utilizing processing techniques well known to those skilled in the art. For example, any nanosheet transistor fabrication process can be used in forming the bottom transistors illustrated in FIGS. 6A-6E.

A bottom transistor frontside interlayer dielectric (ILD) layer 22 is located in the bottom device region illustrated in FIGS. 6A-6E. The bottom transistor frontside ILD layer 22 can include a first bottom transistor frontside ILD portion 22A that is located beneath the bottom transistor first source/drain region 28A and the bottom transistor second source/drain region 28B of each bottom transistor and a second bottom transistor frontside ILD portion 22B that is located above and adjacent to the bottom transistor first source/drain region 28A and the bottom transistor second source/drain region 28B of each bottom transistor. The first bottom transistor frontside ILD portion 22A is optional and, in some embodiments, is omitted from the structure. When the first bottom transistor frontside ILD portion 22A is omitted, the bottom transistor first source/drain region 28A and the bottom transistor second source/drain region 28B of each bottom transistor can be located on a non-etched portion of a semiconductor device layer 14 of the substrate.

The initial structure illustrated in FIGS. 6A-6E can also include a bottom gate cut region that includes a bottom gate cut dielectric structure 34 that is located between each bottom transistor gate structure 30 that has been subjected to a bottom gate cut process. Each bottom gate cut dielectric structure 34 is spaced apart from each bottom transistor gate structure 30 that has been subjected to a bottom gate cut process by a bottom gate cut spacer 32.

The substrate of the initial structure illustrated in FIGS. 6A-6E includes a semiconductor base layer 10, an etch stop layer 12, and a semiconductor device layer 14. While the present application describes and illustrates that the substrate includes the semiconductor base layer 10, the etch stop layer 12, and the semiconductor device layer 14, embodiments are contemplated in which the semiconductor base layer 10 or the etch stop layer 12, or both the semiconductor base layer 10 and the etch stop layer 12 are omitted.

The substrate can also include a trench isolation structure 18 that can include a trench dielectric liner 16 located along a sidewall and a bottom surface of the trench isolation structure 18. The trench dielectric liner 16 is optional and can be omitted in some embodiments of the present application. The trench isolation structure 18 and, if present, the trench dielectric liner 16, are located in an upper portion of the semiconductor device layer 14. As is illustrated in FIG. 6A, each bottom gate cut dielectric structure 34 lands on a surface of the trench isolation structure 18, and the trench isolation structure 18 is located adjacent to a non-etched portion of the semiconductor device layer 14.

The semiconductor base layer 10 is composed of a first semiconductor material, and the semiconductor device layer 14 is composed of a second semiconductor material. As used throughout the present application, the term “semiconductor material” denotes a material that has semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the semiconductor device layer 14 can be compositionally the same as, or compositionally different from, the first semiconductor material that provides the semiconductor base layer 10. In some embodiments of the present application, the etch stop layer 12 is composed of a third semiconductor material that is compositionally different from the first semiconductor material that provides the semiconductor base layer 10 and the second semiconductor material that provides the semiconductor device layer 14. In one example, the semiconductor base layer 10 is composed of silicon, the etch stop layer 12 is composed of silicon germanium, and the semiconductor device layer 14 is composed of silicon. The substrate including the semiconductor base layer 10, the etch stop layer 12 and the semiconductor device layer 14 can be formed utilizing techniques well known to those skilled in the art. In one example, the substrate including the semiconductor base layer 10, the etch stop layer 12 and the semiconductor device layer 14 can be formed utilizing an epitaxial growth process. Throughout the present application, the terms “epitaxial growth” or “epitaxially growing” mean the growth of a semiconductor material on a growth surface of another semiconductor material, in which the semiconductor material being grown has the same crystalline characteristics as the growth surface of the another semiconductor material. In another example, the substrate including the semiconductor base layer 10, the etch stop layer 12 and the semiconductor device layer 14 can be formed by a wafer bonding process or by an Separation by IMplantation of Oxygen (SiMOX) process.

The trench dielectric liner 16 is composed of a trench dielectric liner material such as, for example, silicon nitride. The trench isolation structure 18 is composed of any trench dielectric material such as, for example, silicon dioxide. In some embodiments, the trench isolation structure 18 can have a topmost surface that is substantially coplanar with a topmost surface of the semiconductor device layer 14. In other embodiments, the trench isolation structure 18 can have a topmost surface that is vertically offset (i.e., higher or lower) than a topmost surface of the semiconductor device layer 14. The trench isolation structure 18 and the trench dielectric liner 16 can be formed utilizing a conventional shallow trench isolation process in which a trench is formed into the semiconductor device layer 14 by lithography and etching. A trench dielectric liner material layer and a trench dielectric material are then formed into the trench utilizing separate deposition processes. After deposition of the trench dielectric liner material layer and a trench dielectric material, a planarization process and/or a recess etch can be used.

Each bottom semiconductor channel material nanosheet 20 of the vertical stack of spaced apart bottom semiconductor channel material nanosheets is composed of a fourth semiconductor material. The fourth semiconductor material that provides each bottom semiconductor channel material nanosheet 20 can be compositionally the same as, or compositionally different from, the second semiconductor material that provides the semiconductor device layer 14. In one example, each bottom semiconductor channel material nanosheet 20 is composed of Si or SiGe. Each bottom semiconductor channel material nanosheet 20 in the vertical stack of spaced apart bottom semiconductor channel material nanosheets may have the same width and length. The height (i.e., vertical thickness) of each bottom semiconductor channel material nanosheet 20 in the vertical stack of spaced apart bottom semiconductor channel material nanosheets can be the same or different. The vertical stack of spaced apart bottom semiconductor channel material nanosheets can be formed utilizing nanosheet device processes techniques well known to those skilled in the art.

The bottom transistor frontside ILD layer 22 including the first bottom transistor frontside ILD portion 22A and the second bottom transistor frontside ILD portion 22B can be composed of one or more ILD materials. The one or more ILD materials that can be used in providing the bottom transistor frontside ILD layer 22 including the first bottom transistor frontside ILD portion 22A and the second bottom transistor frontside ILD portion 22B includes, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0 (all dielectric constants mentioned herein are measured in a vacuum unless otherwise noted). The bottom transistor frontside ILD layer 22 including the first bottom transistor frontside ILD portion 22A and the second bottom transistor frontside ILD portion 22B can be formed by a deposition process including, but not limited to, chemical vapor deposition (CVD), plasma enhanced chemical vapor deposition (PECVD) or spin-on coating. A planarization process such as, for example, chemical mechanical planarization (CMP) can follow the deposition of the second bottom transistor frontside ILD portion 22B. Note that the second bottom transistor frontside ILD portion 22B is formed on top of the first bottom transistor frontside ILD portion 22A. The first bottom transistor frontside ILD portion 22A is optional and, in some embodiments, is omitted from the structure such that 22A and 22B are identical.

The bottom transistor gate spacer 24, the bottom transistor inner spacers 26 and the bottom gate cut spacer 32 can be composed of a dielectric spacer material. In some embodiments, the bottom transistor gate spacer 24, the bottom transistor inner spacers 26 and the bottom gate cut spacer 32 can be composed of a same dielectric spacer material. In other embodiments, the bottom transistor gate spacer 24 is composed of a compositionally different dielectric spacer material than the bottom transistor inner spacers 26 and/or the bottom gate cut spacer 32. In such embodiments, the bottom transistor inner spacers 26 can be composed of a compositionally same, or different dielectric spacer material than the bottom gate cut spacer 32. Exemplary dielectric spacer materials that can be used in providing the bottom transistor gate spacer 24, the bottom transistor inner spacers 26 and the bottom gate cut spacer 32 include, but are not limited to, silicon dioxide, SiN, SiBCN, SiOCN SiOC, or “low-k” materials. The bottom transistor gate spacer 24, the bottom transistor inner spacers 26 and the bottom gate cut spacer 32 can be formed utilizing techniques well known in the art.

Each bottom transistor gate structure 30 includes a bottom transistor gate dielectric material and a bottom transistor gate electrode, both of which are not separately shown, but intended to be within the region defined by the bottom transistor gate structure 30. As is known to those skilled in the art, a gate dielectric material directly contacts a physically exposed surface(s) of the semiconductor channel region, and a gate electrode is formed on the gate dielectric material. The bottom transistor gate dielectric material may have a dielectric constant of 4.0 or greater. Illustrative examples of bottom transistor gate dielectric materials that can be used include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc, Ta)O₃), and/or lead zinc niobite (Pb(Zn, Nb)O). The bottom transistor gate dielectric material can further include dopants such as lanthanum (La), aluminum (Al) and/or magnesium (Mg). The bottom transistor gate electrode can include a work function metal (WFM) and optionally a conductive metal. The WFM can be used to set a threshold voltage of the bottom transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co). The bottom transistor gate structure 30 can be formed by deposition, followed by planarization.

The bottom transistor first source/drain region 28A and the bottom transistor second source/drain region 28B can be composed of fifth semiconductor material and a first dopant. The fifth semiconductor material that provides the bottom transistor first source/drain region 28A and the bottom transistor second source/drain region 28B is composed of one of the semiconductor materials mentioned above. The fifth semiconductor material that provides the bottom transistor first source/drain region 28A and the bottom transistor second source/drain region 28B can be compositionally the same as, or compositionally different from, the fourth semiconductor material that provides each bottom semiconductor channel material nanosheet 20. The first dopant can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, the bottom transistor first source/drain region 28A and the bottom transistor second source/drain region 28B of each bottom transistor can have a dopant concentration of from 1×10²⁰ atoms/cm³ to 1×10²¹ atoms/cm³. The bottom transistor first source/drain region 28A and the bottom transistor second source/drain region 28B extend outward from a sidewall of each bottom semiconductor channel material nanosheet 20. The bottom transistor first source/drain region 28A and the bottom transistor second source/drain region 28B can be formed by epitaxial growth in which a dopant ion is present during the deposition of the fifth semiconductor material.

The bottom gate cut dielectric structure 34 can be composed of any gate cut dielectric material including, for example, silicon oxide or any “low-k” material. The gate cut dielectric material that provides the bottom gate cut dielectric structure 34 is compositionally different from the dielectric spacer material that provides the bottom gate cut spacer 32. The bottom gate cut dielectric structure 34 can be formed utilizing any gate cut process that is well known to those skilled in the art.

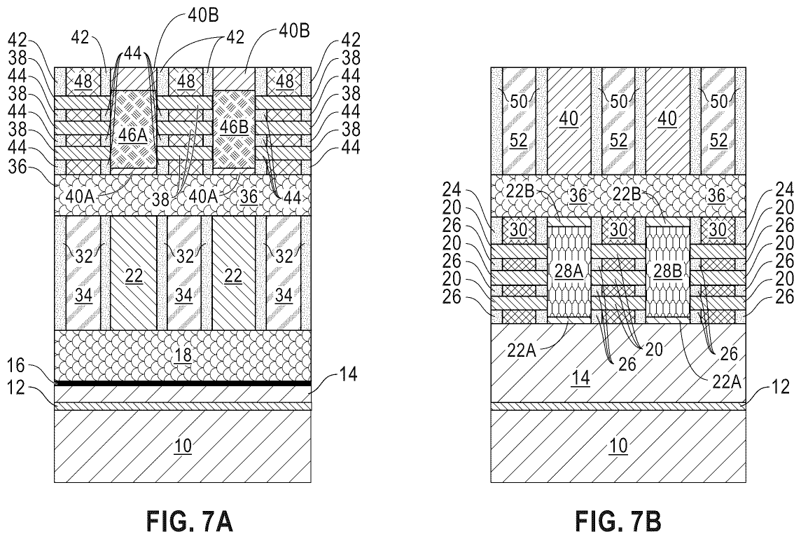

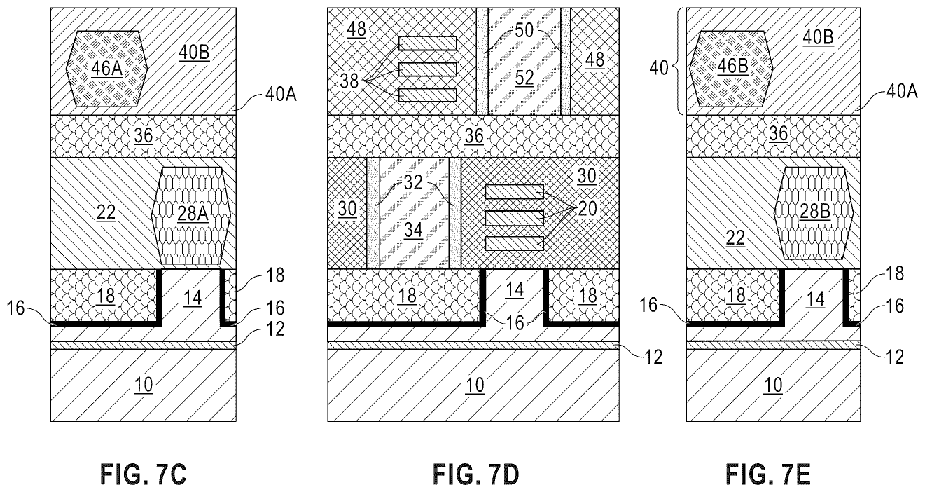

Next, a top transistor is formed in a staggered configuration above the bottom transistor as is illustrated in FIGS. 7A-7E. In the present application and as illustrated in FIGS. 7A-7B, the top transistor is located in a top device region that is located above the bottom device region that includes the bottom transistor. The top transistor is positioned on top of bonding dielectric layer 36. Bonding dielectric layer 36 separates the top transistor from the bottom transistor. The bonding dielectric layer 36 electrically isolates the top transistor from the bottom transistor. In the embodiment illustrated in the present application, three top transistor gates are illustrated by way of one example. Each top transistor is a nanosheet transistor including a top transistor gate structure 48 wrapped around a vertical stack of spaced apart top semiconductor channel material nanosheets (each vertical stack of spaced apart top semiconductor channel material nanosheets includes a plurality of top semiconductor channel material nanosheets 38). Each top transistor further includes a top transistor first source/drain region 46A located on one side of the vertical stack of spaced apart top semiconductor channel material nanosheets and a top transistor second source/drain region 46B located on a second side of the vertical stack of spaced apart top semiconductor channel material nanosheets. In FIG. 7A, the other source/drain region for the top transistors on the left hand side and the right hand side are not shown in the cross sectional view. Each top transistor also includes a top transistor gate spacer 42 and top transistor inner spacers 44. The top transistor inner spacers 44 are used as supporting elements for the vertical stack of spaced apart top semiconductor channel material nanosheets. The top transistor gate spacer 42 is present along a sidewall of the top transistor gate structure 48. Each top transistor can be formed utilizing processing techniques well known to those skilled in the art. For example, any nanosheet transistor fabrication process can be used in forming the top transistors illustrated in FIGS. 7A-7E. Notably, the top transistors are formed by attaching (via a bonding process) a wafer to the initial structure illustrated in FIGS. 6A-6E utilizing bonding dielectric layer 36 as an attachment structure and thereafter processing the wafer to include top transistors as illustrated in FIGS. 7A-7E.

A top transistor frontside ILD layer 40 is located in the top device region including the top transistor. The top transistor frontside ILD layer 40 can include a first top transistor frontside ILD portion 40A that is located beneath the top transistor first source/drain region 46A and the top transistor second source/drain region 46B and a second top transistor frontside ILD portion 40B that is located above and adjacent to the top transistor first source/drain region 46A and the top transistor second source/drain region 46B.

A top gate cut region can also be present in the top device region. The top gate cut region includes a top gate cut dielectric structure 52 that is located between each top transistor gate structure 48 that has been subjected to a top gate cut process. Each top gate cut dielectric structure 52 is spaced apart from each top transistor gate structure 48 that has been subjected to a top gate cut process accompanied by a top gate cut spacer 50.

The bonding dielectric layer 36 is composed of a bonding dielectric material such as, but are not limited to, tetraethyl orthosilicate (TEOS), SiO₂, silicon carbon nitride (SiCN) and/or carbon-doped silicon oxide (SiCOH). The bonding dielectric layer 36 is typically formed on a wafer utilizing a deposition process such as, for example, CVD, PECVD or physical vapor deposition (PVD).

Each top semiconductor channel material nanosheet 38 of the vertical stack of spaced apart top semiconductor channel material nanosheets is composed of a sixth semiconductor material. The sixth semiconductor material that provides each top semiconductor channel material nanosheet 38 can be compositionally the same as, or compositionally different from, the fourth semiconductor material that provides each bottom semiconductor channel material nanosheet 20. In one example, each top semiconductor channel material nanosheet 38 is composed of Si or SiGe. Each top semiconductor channel material nanosheet 38 in the vertical stack of spaced apart top semiconductor channel material nanosheets may have the same width and length. The height (i.e., vertical thickness) of each top semiconductor channel material nanosheet 38 in the vertical stack of spaced apart top semiconductor channel material nanosheets can be the same or different. The vertical stack of spaced apart top semiconductor channel material nanosheets can be formed utilizing nanosheet device processes techniques well known to those skilled in the art.

The top transistor frontside ILD layer 40 including the first top transistor frontside ILD portion 40A and the second top transistor frontside ILD portion 40B can be composed of one or more ILD materials as mentioned above for the bottom transistor frontside ILD layer 22. The top transistor frontside ILD layer 40 including the first top transistor frontside ILD portion 40A and the second top transistor frontside ILD portion 40B can be formed by a deposition process including, but not limited to, CVD, PECVD or spin-on coating. A planarization process such as, for example, CMP can follow the deposition of the second top transistor frontside ILD portion 40B. Note that the second top transistor frontside ILD portion 40B is formed on top of the first top transistor frontside ILD portion 40A. In other embodiments elements, the first and second top transistor frontside ILD portions (40A and 40B, respectively) are identical and are deposited by the above mentioned process without the need for any CMP process.

The top transistor gate spacer 42, the top transistor inner spacers 44 and the top gate cut spacer 50 can be composed of a dielectric spacer material as mentioned above for the bottom transistor gate spacer 24, the bottom transistor inner spacers 26 and the bottom gate cut spacer 32. In some embodiments, the top transistor gate spacer 42, the top transistor inner spacers 44 and the top gate cut spacer 50 can be composed of a same dielectric spacer material. In other embodiments, the top transistor gate spacer 42 is composed of a compositionally different dielectric spacer material than the top transistor inner spacers 44 and/or the top gate cut spacer 50. In such embodiments, the top transistor inner spacers 44 can be composed of a compositionally same or different dielectric spacer material than the top gate cut spacer 50. The top transistor gate spacer 42, the top transistor inner spacers 44 and the top gate cut spacer 50 can be formed utilizing techniques well known in the art.

Each top transistor gate structure 48 includes a top transistor gate dielectric material and a top transistor gate electrode, both of which are not separately shown, but intended to be within the region defined by the top transistor gate structure 48. The top gate dielectric material includes one of the dielectric materials mentioned above for the bottom transistor gate dielectric material. The top gate dielectric material can be compositionally the same as, or compositionally different from, the bottom gate dielectric material. The top transistor gate electrode can include a work function metal (WFM) and optionally a conductive metal, both as defined above for the bottom transistor gate electrode. The WFM that provides the top transistor gate electrode can be compositionally the same as, or compositionally different from, the WFM that provides the bottom transistor gate electrode. The WFM that provides the top transistor gate electrode can provide a same or a different threshold voltage shift as compared to the WFM or the bottom transistor gate electrode. The optional conductive metal of the top transistor gate electrode can be compositionally the same as, or compositionally different from, the optional conductive metal of the bottom transistor gate electrode. The top transistor gate structure 48 can be formed by deposition, followed by planarization.

The top transistor first source/drain region 46A and the top transistor second source/drain region 46B of each top transistor can be composed of a seventh semiconductor material and a second dopant. The seventh semiconductor material that provides the top transistor first source/drain region 46A and the top transistor second source/drain region 46B is composed of one of the semiconductor materials mentioned above. The seventh semiconductor material that provides the top transistor first source/drain region 46A and the top transistor second source/drain region 46B can be compositionally the same as, or compositionally different from, the sixth semiconductor material that provides each top semiconductor channel material nanosheet 38. The second dopant can be either a p-type dopant or an n-type dopant, both as defined above for the first dopant. The second dopant can be of a same conductivity type or a different conductivity type as the first dopant. In one example, top transistor first source/drain region 46A and the top transistor second source/drain region 46B of each bottom transistor can have a dopant concentration of from 4×10²⁰ atoms/cm³ to 3×10²¹ atoms/cm³. The top transistor first source/drain region 46A and the top transistor second source/drain region 46B extend outward from a sidewall of each top semiconductor channel material nanosheet 38. The top transistor first source/drain region 46A and the top transistor second source/drain region 46B can be formed by epitaxial growth in which a dopant ion is present during the deposition of the seventh semiconductor material.

The top gate cut dielectric structure 52 can be composed of any gate cut dielectric material including, for example, silicon oxide or “low-k” materials. The gate cut dielectric material that provides the top gate cut dielectric structure 52 is compositionally different from the dielectric spacer material that provides the top transistor gate spacer 42. The top gate cut dielectric structure 52 can be formed utilizing any gate cut process that is well known to those skilled in the art.

It is noted that the top transistor is stacked above the bottom transistor in a staggered configuration as defined above. It is also noted that the top transistors and the top gate cut dielectric structure 52 land on the bonding dielectric layer 36. In some embodiments, the bottom transistor can be of a same conductivity type as the top transistor, i.e., bottom and top transistors are both n-type transistors or p-type transistors. In other embodiments, the bottom transistor can be of a different conductivity type as the top transistor, i.e., the bottom transistor is p-type and the top transistor is n-type, or the bottom transistor is n-type and the top transistor is p-type.

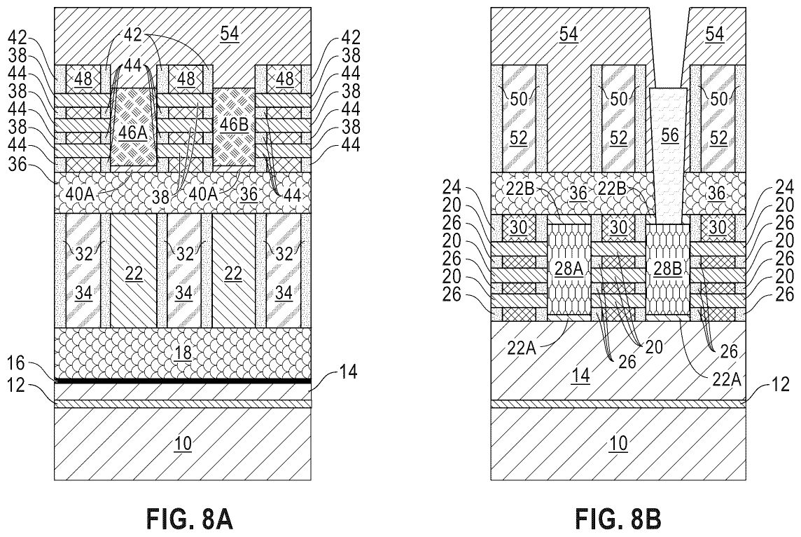

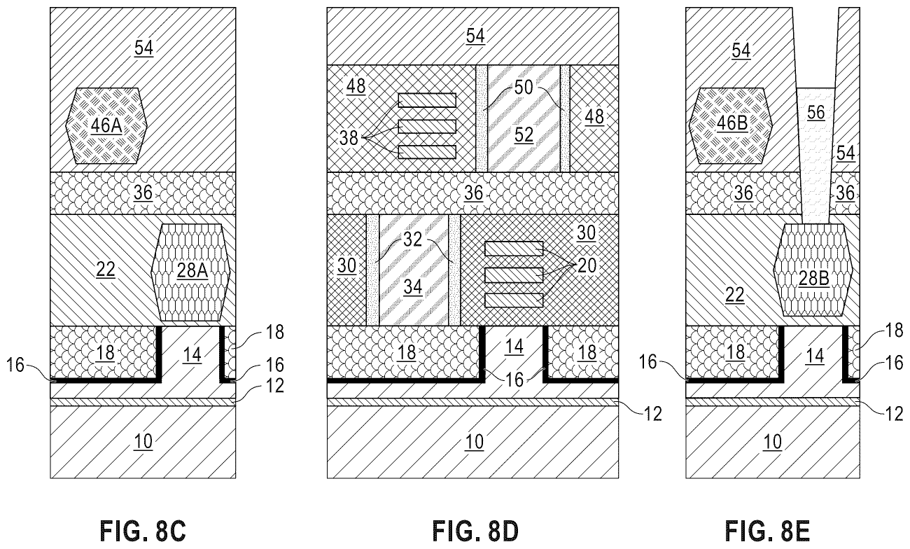

Next, and as is illustrated in FIGS. 8A-8E, a frontside bottom source/drain contact structure 56 is formed in contact with the bottom transistor second source/drain region 28B of the bottom transistor. The frontside bottom source/drain contact structure 56 is formed by first forming an additional ILD layer on the top transistor frontside ILD layer 40 as well as on top of each top transistor and on top of the top gate cut dielectric structure 52. Collectively, the top transistor frontside ILD layer 40 and the additional ILD layer form a top transistor frontside ILD multilayered structure 54. The additional ILD layer used in providing the top transistor frontside ILD multilayered structure 54 can include one of the dielectric materials mentioned above for the top transistor frontside ILD layer 40. The additional ILD layer can be composed of a compositionally same, or compositionally different, ILD material than that provides the top transistor frontside ILD layer 40. The additional ILD layer can be formed by a deposition process such as, for example, CVD, PECVD, or spin-on coating. The formation of the frontside bottom source/drain contact structure 56 continues by forming a frontside contact opening that extends entirely through the top device region and the bonding dielectric layer 36 and extends partially into the bottom device region (physically exposing the bottom transistor second source/drain region 28B). The frontside contact opening can be formed by lithographic patterning. Frontside bottom source/drain contact structure 56 can be formed by deposition, planarization and a recess etching process. The frontside bottom source/drain contact structure 56 is composed of at least a contact conductor material. The contact conductor material can include, for example, a conductive metal such as, for example, W, Cu, Al, Co, Ru, Mo, Os, Ir, Rh, or an alloy thereof. The frontside bottom source/drain contact structure 56 can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above.

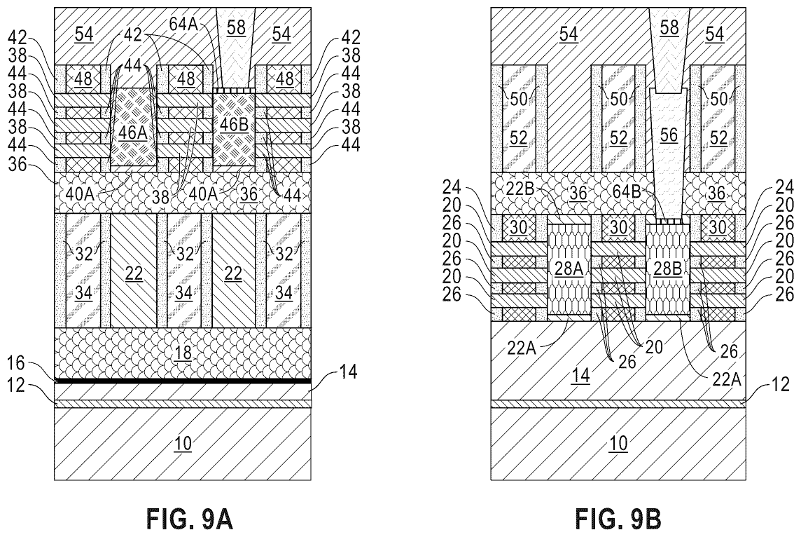

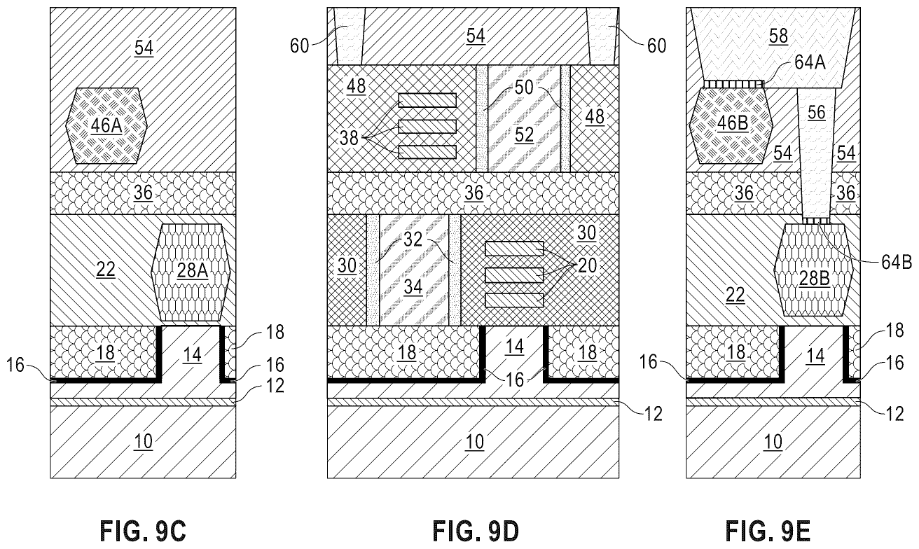

Next, and as is illustrated in FIGS. 9A-9E, frontside top contact structures including a frontside top gate contact structure 60 in contact with the top transistor gate electrode of the top transistor, and a frontside top source/drain contact structure 58 in contact with a top transistor second source/drain region 46B of the top transistor and with the frontside bottom source/drain contact structure 56. Prior to forming the frontside top contact structures, the space in the frontside contact opening above the frontside bottom source/drain contact structure 56 is filled with an ILD material. The ILD material that is formed typically includes a compositionally same ILD material as the ILD material used in providing the additional ILD layer. This step re-establishes the integrity of the top transistor frontside ILD multilayered structure 54.

The frontside top gate contact structure 60 and the frontside top source/drain contact structure 58 can be composed of at least a contact conductor material as mentioned above. The frontside top gate contact structure 60 and/or the frontside top source/drain contact structure 58 can also include a contact liner as mentioned above. The frontside top gate contact structure 60 and the frontside top source/drain contact structure 58 can be formed by a metallization process which includes forming a contact opening into the top transistor frontside ILD multilayered structure 54, and then forming by deposition and planarization the frontside top contact structure in the contact opening. In the illustrated embodiment, the frontside top source/drain contact structure 58 and the frontside bottom source/drain contact structure 56 electrically connect the top transistor second source/drain region 46B to the bottom transistor second source/drain region 28B as is illustrated in FIG. 9E. In some embodiments of the present application, a silicidation anneal can be performed after forming the frontside top contact structures. The silicidation anneal is performed at a temperature of 550 °C or above to form a metal silicide layer between a source/drain region of a transistor and a frontside source/drain contact structure. Notably, a first metal silicide layer 64A can be formed between the top transistor second source/drain region 46B and the frontside top source/drain contact structure 58 and a second metal silicide layer 64B can be formed between the bottom transistor second source/drain region 28B and the frontside bottom source/drain contact structure 56. The presence of the metal silicide layer facilitates a reduction in the contact resistance between the source/drain region and the frontside source/drain contact structure.

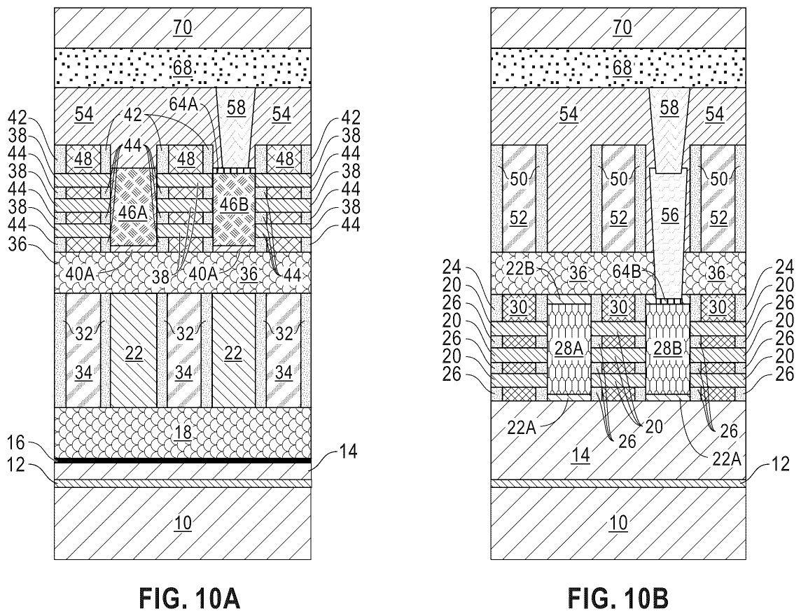

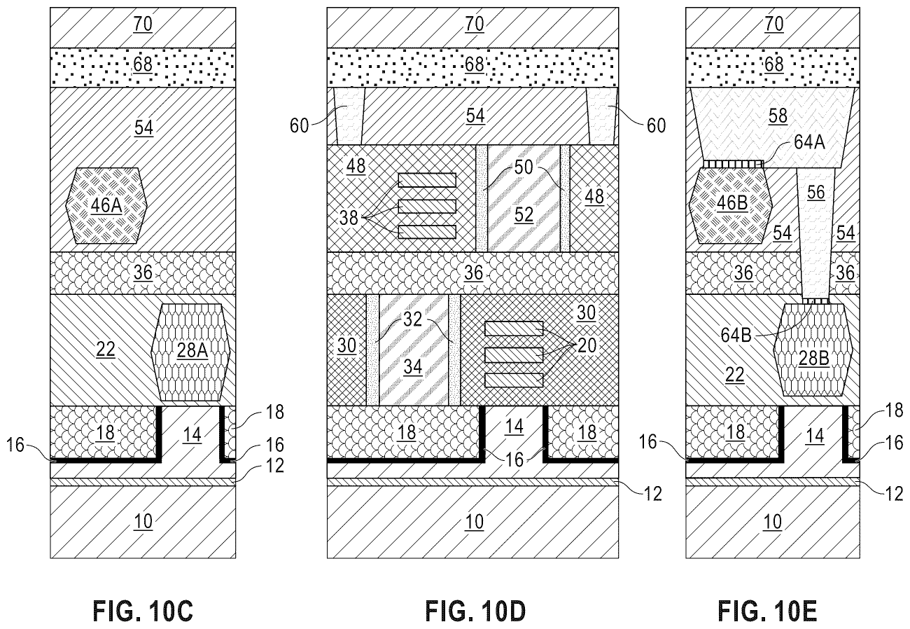

Next, a frontside BEOL structure 68 is formed and thereafter the frontside BEOL structure 68 is bonded to a carrier wafer 70 so as to provide the exemplary structure shown in FIGS. 10A-10E. The frontside BEOL structure 68 is composed of an interconnect dielectric region having frontside metal wiring embedded therein. The interconnect dielectric region includes one or more interconnect dielectric material layers. The interconnect dielectric material layers can be composed of low-k dielectric materials, such as SiCHO, SiCNO, SiNCHO, or at least one of the ILD materials mentioned above. The frontside metal wiring can be in the form of metal lines, metal vias, a metal via/metal line combination or any combinations thereof. The frontside metal wiring is composed of an electrically conductive metal, an electrically conductive metal alloy, or an electrically conductive compound. Illustrative examples of electrically conductive metals that can be used include, but are not limited to, Cu, Al, Co, Ru, Mo, Os, Ir, or Rh. An illustrative electrically conductive alloy that can be used includes, but is not limited to, a Cu-Al alloy. Illustrative examples of electrically conductive compounds that can be used include, but are not limited to, PtCoO₂, PdCoO₂, MoP, NbAs, NbP, TaAs, TaP, MoTe₂, WTe₂, CoSi, RhSi, AlPt, GaPt, GaPd, or doped multilayer graphene.

The frontside BEOL structure 68 can be formed utilizing any well-known BEOL process including a damascene process or a subtractive metal etch process. The frontside BEOL structure 68 can be configured to transmit signals to the top and bottom transistors. After forming the frontside BEOL structure 68, carrier wafer 70 is formed on the frontside BEOL structure 68. Carrier wafer 70 can include a semiconductor material as defined above. Carrier wafer 70 can be bonded to the frontside BEOL structure 68 utilizing any bonding process that is well known to those skilled in the art.

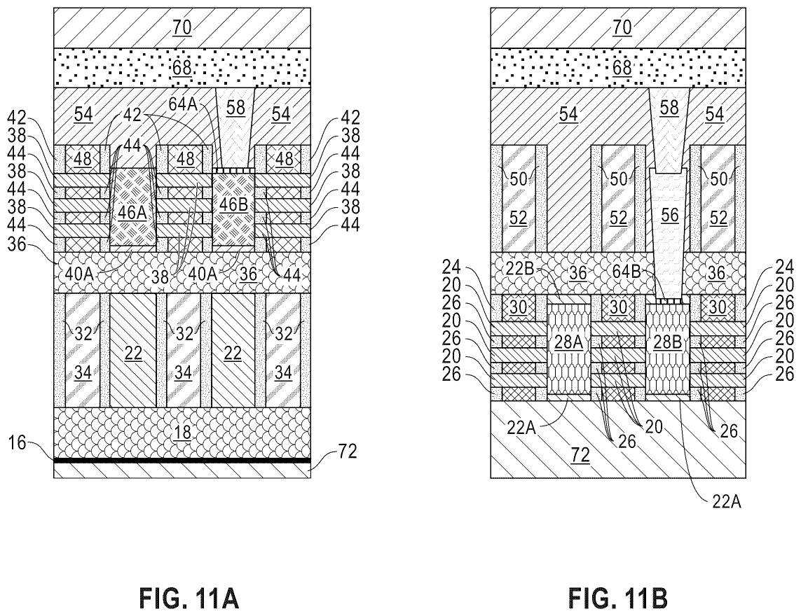

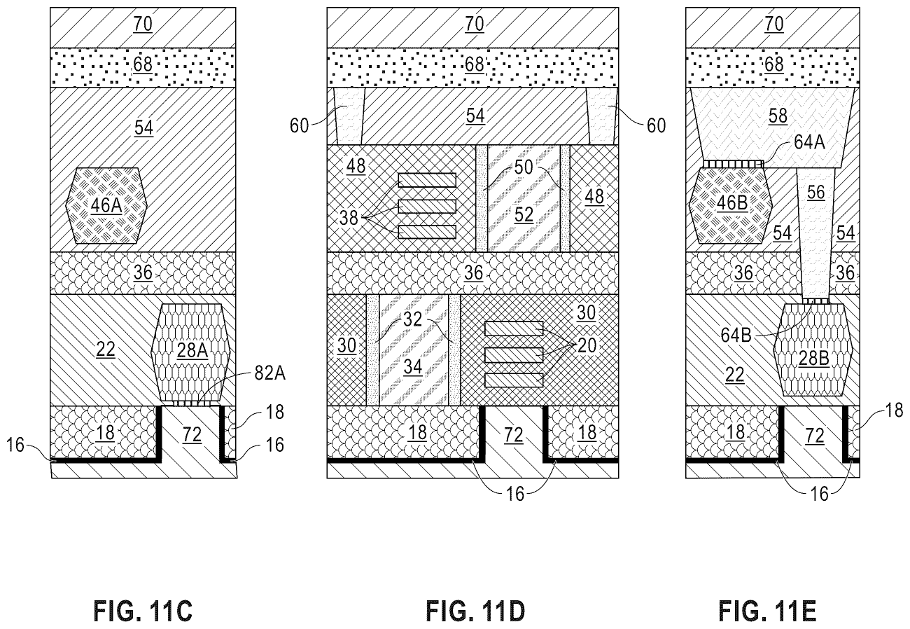

After forming the exemplary structure show in FIGS. 10A-10E, the substrate beneath the bottom transistor is removed and replaced with a backside ILD layer 72 so as to provide the exemplary structure illustrated in FIGS. 11A-11E. The removal of the substrate includes flipping the exemplary structure 180° to physically expose the backside of the substrate. For clarity, the flipping step is not shown in the drawings. Flipping can be performed by hand or by utilizing a mechanical means such as, for example, a robot arm. After flipping, and in the illustrated embodiment, the semiconductor base layer 10 is physically exposed and the physically exposed semiconductor base layer 10 is removed utilizing a material removal process that is selective in removing the semiconductor material that provides the semiconductor base layer 10. The removal of the semiconductor base layer 10 reveals the etch stop layer 12. The etch stop layer 12 can then be removed utilizing a material removal process that is selective in removing the material that provides the etch stop layer 12. The removal of the etch stop layer 12 physically exposes the semiconductor device layer 14. It is noted that the removal of the semiconductor base layer 10 and/or etch stop layer 12 can be omitted when such layers are not present. Next, the semiconductor device layer 14 can be removed utilizing a material removal process that is selective in removing the semiconductor device layer 14. In some embodiments and as is illustrated in FIGS. 10A-1E an entirety of the semiconductor device layer 14 is removed. In other embodiments (not shown), a portion of the semiconductor device layer 14 is removed.

After substrate removal, backside ILD layer 72 is formed. The backside ILD layer 72 is composed of an ILD material as mentioned above. The backside ILD layer 72 can be formed by deposition (e.g., CVD, PECVD or spin-on coating), followed by a planarization process.

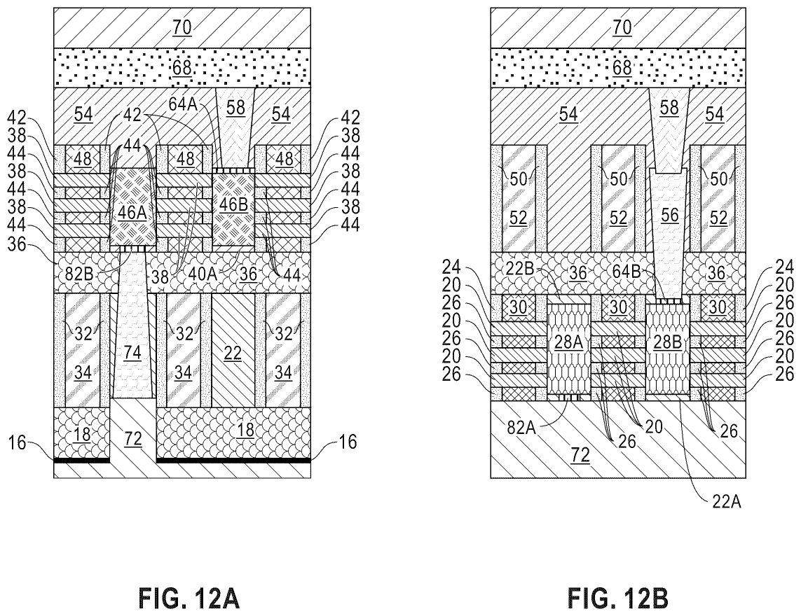

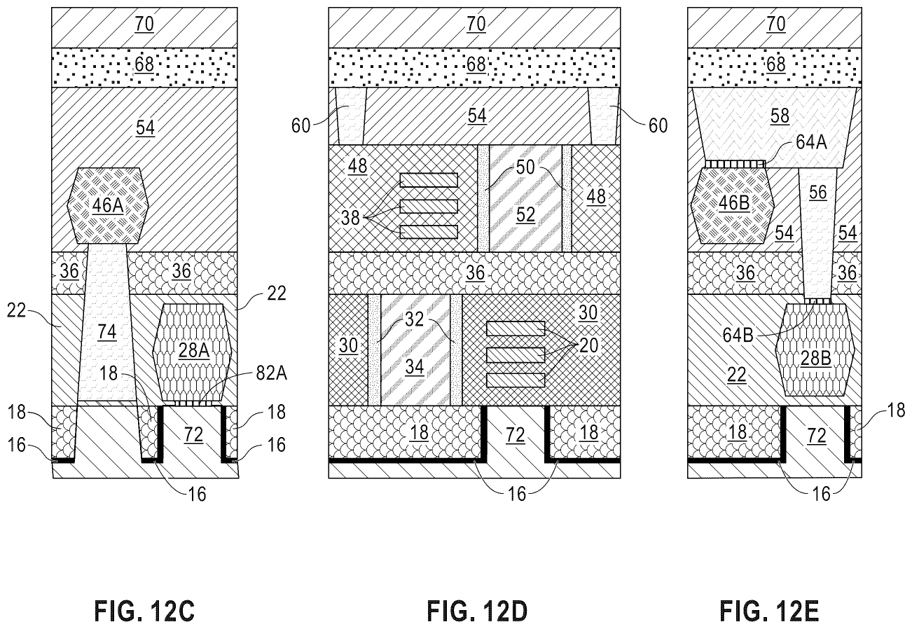

Next, and as illustrated in FIGS. 12A-12E, a backside top source/drain contact structure 74 is formed in contact with top transistor first source/drain region 46A. The backside top source/drain contact structure 74 can be composed of at least a contact conductor material as mentioned above. The backside top source/drain contact structure 74 can also include a contact liner as mentioned above. The backside top source/drain contact structure 74 can be formed by a metallization process as mentioned above followed by a recess etching process. After forming the backside top source/drain contact structure 74, additional ILD material is formed to re-establish the integrity of the backside ILD layer 72.

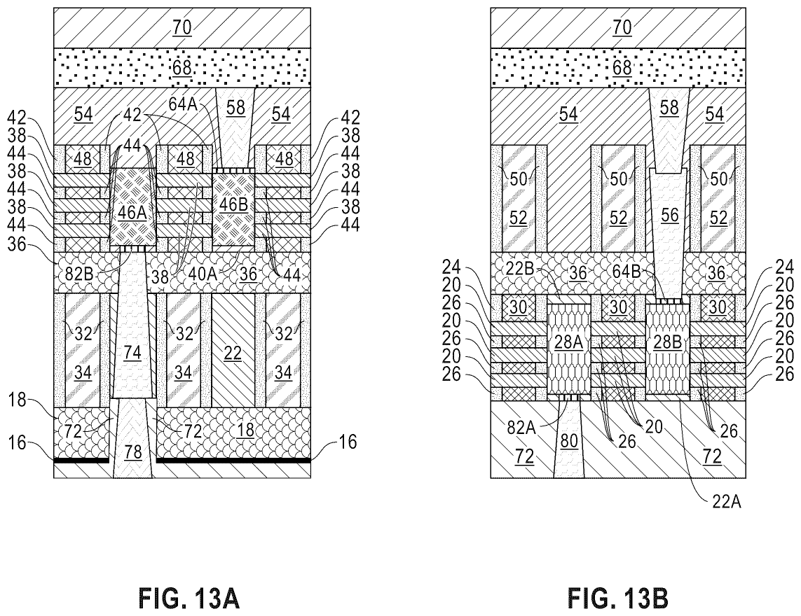

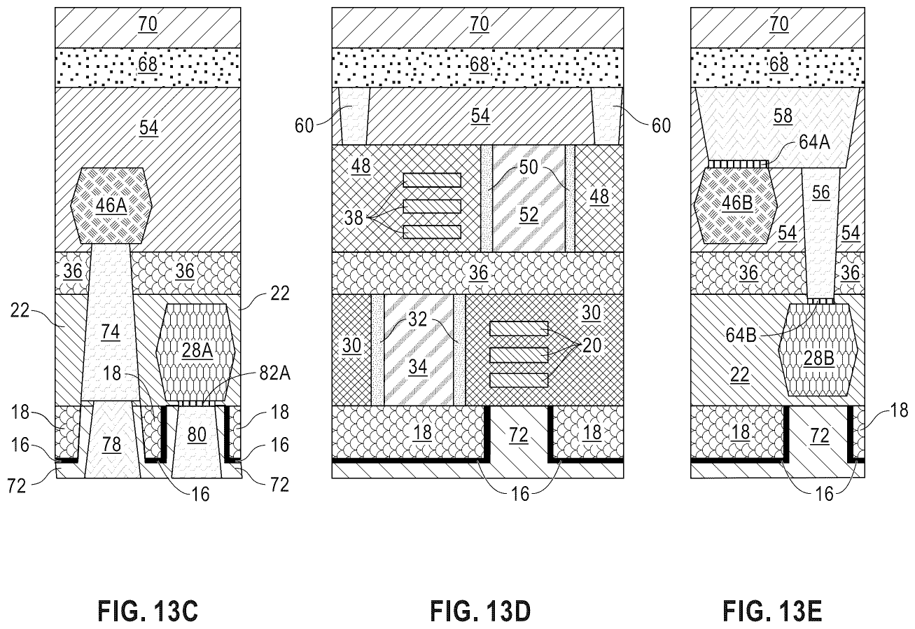

Next, and as illustrated in FIGS. 13A-13E, a backside bottom source/drain contact structure 80 is formed in contact with the bottom transistor first source/drain region 28A and a backside top source/drain extension contact structure 78 is formed in contact with the backside top source/drain contact structure 74. The backside bottom source/drain contact structure 80 and the backside top source/drain extension contact structure 78 can be composed of at least a contact conductor material as mentioned above. The backside bottom source/drain contact structure 80 and the backside top source/drain extension contact structure 78 can also include a contact liner as mentioned above. The backside bottom source/drain contact structure 80 and the backside top source/drain extension contact structure 78 can be formed by a metallization process as defined above. In some embodiments of the present application, a silicidation anneal as described above can be performed after forming the backside bottom source/drain contact structure 80. The silicidation anneal forms a metal silicide layer between a source/drain region of a transistor and a backside source/drain contact structure. Notably, a third metal silicide layer 82B can be formed between the top transistor first source/drain region 46A and the backside top source/drain contact structure 74 and a fourth metal silicide layer 82A can be formed between the bottom transistor first source/drain region 28A and the backside bottom source/drain contact structure 80. The presence of the metal silicide layer facilitates a reduction in the contact resistance between the source/drain region and the backside source/drain contact structure.

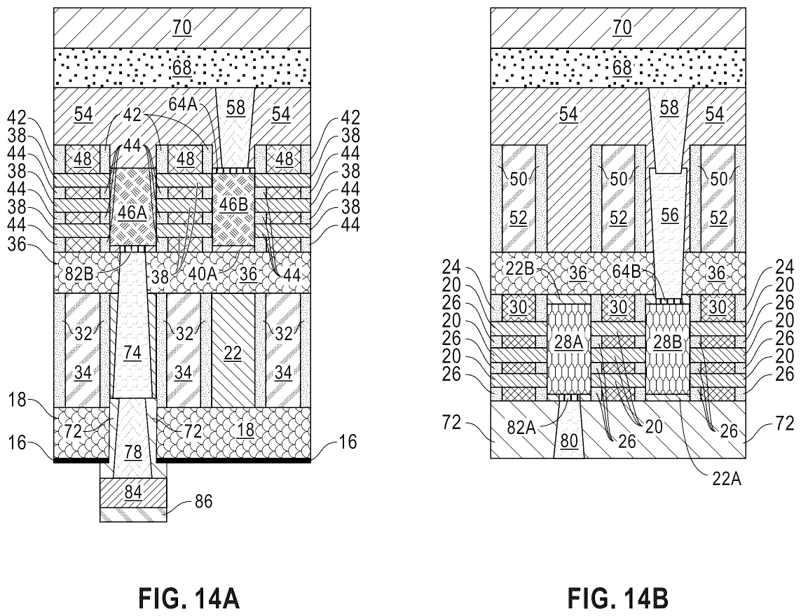

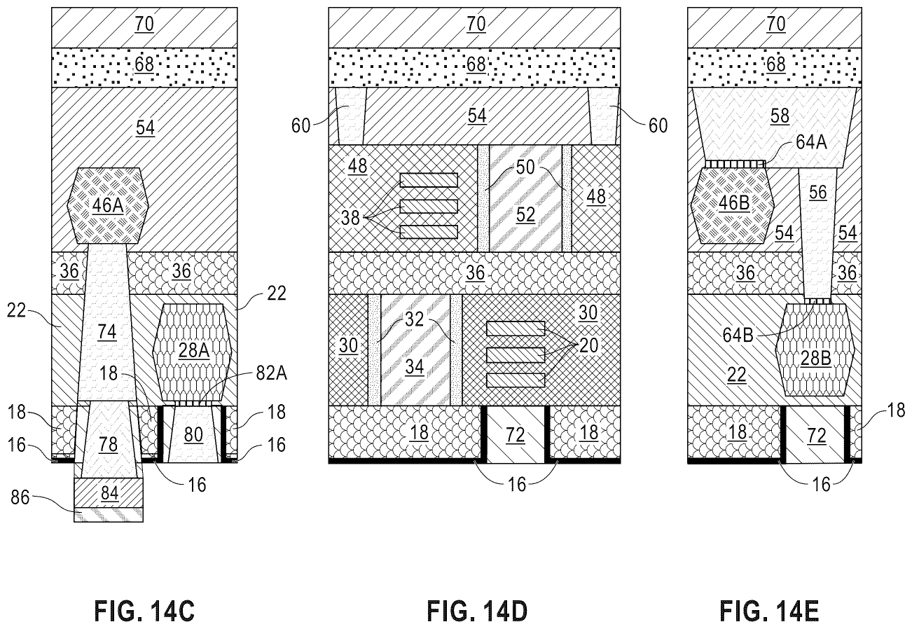

After forming the exemplary structure shown in FIGS. 13A-13E, a MTJ structure 84 and a SOT channel layer 86 are formed to provide the exemplary structure illustrated in FIGS. 14A-14E. Collectively, the MTJ structure 84 and the SOT channel layer 86 form a three-terminal memory element in accordance with an embodiment of the present application. Although not depicted in FIGS. 14A-14E, magnetic oxide layer 85 can be positioned between the MTJ structure 84 and the SOT channel layer 86 providing another three-terminal memory element of the present application (this embodiment is depicted in FIGS. 4A-4E). The MTJ structure 84 includes, from bottom to top, a magnetic free layer, a tunnel barrier layer and a magnetic reference layer; the various layers of the MTJ structure 84 are not specifically illustrated, but are intended to be within the area represented by the MTJ structure 84. In the embodiment illustrated in in FIGS. 14A-14E, the magnetic free layer of the MTJ structure 84 forms an interface with the SOT channel layer 86. In embodiments in which a magnetic oxide layer 85 is present, the magnetic free layer of the MTJ structure 84 forms an interface with the magnetic oxide layer.

The magnetic free layer of the MTJ structure 84 is composed of at least one magnetic material with a magnetization that can be changed in orientation relative to the magnetization orientation of the magnetic reference material in the MTJ structure 84. Exemplary magnetic materials that can be used in providing the magnetic free layer include, but are not limited to, alloys and/or multilayers of cobalt, iron, alloys of cobalt-iron, nickel, alloys of nickel-iron, and alloys of cobalt-iron-boron. The magnetic free layer can have a thickness from 1 nm to 10 nm; although other thicknesses are possible and can be used as the thickness of the magnetic free layer.

The tunnel barrier layer of the MTJ structure 84 is composed of an insulator material and is formed at such a thickness as to provide an appropriate tunneling resistance. Exemplary materials for the tunnel barrier layer include, but are not limited to, magnesium oxide, aluminum oxide, titanium oxide, or materials of higher electrical tunnel conductance, such as semiconductors or low-bandgap insulators. The thickness of the tunnel barrier layer will depend on the material selected. In one example, tunnel barrier layer can have a thickness from 0.5 nm to 1.5 nm; although other thicknesses are possible as long as the thickness of tunnel barrier layer provides an appropriate tunneling resistance.

The magnetic reference layer of the MTJ structure 84 has a fixed magnetization. The magnetic reference layer is composed of a metal or metal alloy that includes one or more metals exhibiting high spin polarization. In alternative embodiments, exemplary metals for the formation of the magnetic reference layer include iron, nickel, cobalt, chromium, platinum, boron, and manganese. Exemplary metal alloys may include the metals exemplified by the above. In another embodiment, the magnetic reference layer may be a multilayer arrangement having (1) a high spin polarization region formed from of a metal and/or metal alloy using the metals mentioned above, and (2) a region constructed of a material or materials that exhibit strong perpendicular magnetic anisotropy (strong PMA). Exemplary materials with strong PMA that may be used include a metal such as cobalt, nickel, platinum, palladium, iridium, or ruthenium, and may be arranged as alternating layers. The strong PMA region may also include alloys that exhibit strong PMA, with exemplary alloys including cobalt-iron-boron, cobalt-iron-terbium, cobalt-iron-gadolinium, cobalt-chromium-platinum, cobalt-platinum, cobalt-palladium, iron-platinum, and/or iron-palladium. The alloys may be arranged as alternating layers. In one embodiment, combinations of these materials and regions may also be employed. The magnetic reference layer can have a thickness from 1 nm to 30 nm; although other thicknesses are possible and can be used as the thickness of the magnetic reference layer.

The SOT channel layer 86 is composed of any spin-current generating material including, for example, β-W, WN, Ta and/or Pt. In some embodiments, the SOT channel layer 86 is composed of a composite that includes a bi-or multi-layered structure in the form of A/B or A/I/B, where A=β-Ta, β-W, CuₓPt₁₋ₓ, Cu₁₋ₓTaₓ, PdₓPt₁₋ₓ, AuₓPt₁₋ₓ, Pt, Bi₂Se₃, WTe₂, PtTe₂, TaS₂, PtₓRh₁₋ₓ, TaAs, NbAs or any materials known to produce large SOT charge-to-spin conversion efficiency, x is from 0 to 1; and B═Cu, Ag, Au . . . are known good spin-conductors, and with ‘I’ as a poor charge-conductor, but good spin-conductor such as NiO, FeOx, and other magnon-mediated spin-conducting, but charge insulating, ferro-ferri-or antiferro-magnetic materials. The I-layer in this case is used as an interface layer between A and B to facilitate spin-conduction but prevent charge-current shunting.

In embodiments when magnetic oxide layer 85 is present, the magnetic oxide layer 85 is composed of magnetic oxide that provides spin conduction between the MTJ structure 84 and the SOT channel layer 86. Illustrative examples of magnetic oxides that can be used in providing the magnetic oxide layer 85 include, but are not limited to, nickel oxide (NiOₓ), iron oxide (FeOₓ), cobalt oxide (CoOₓ), manganese oxide (MnOₓ) and chromium oxide (CrOₓ). A single magnetic oxide or a multilayered stack of magnetic oxides can be employed in the present application.

In some embodiments, the three-terminal memory element illustrated in FIGS. 14A-14E is replaced with another three-terminal memory element (e.g., an ECRAM) that includes solid-state electrolyte layer 98 positioned between gate layer 96 and channel layer 100 (see, FIGS. 5A-5E). In this embodiment, the gate layer 96 forms an interface with the backside top source/drain extension contact structure 78 (in embodiments including the MTJ structure 84 an uppermost surface of the MTJ structure forms an interface with the backside top source/drain extension contact structure 78). In embodiments in which a proton (H⁺) is used as the mobile ion species to dope the channel layer 100 (preferred for its small size and high mobility), then the channel layer 100 may be composed of channel material such as for example, tungsten oxide (WOₓ), or 2D materials, such as multilayer graphene or a conducting transition-metal dichalcogenide (TMD), including NbSe₂, PtTe₂, TiTe₂, CoTe₂, TaS₂, etc. In the proton embodiment, the solid-state electrolyte layer 98 can be a SiOx-based proton conductor, e.g., phosphosilicate glass (P-SiO₂, PSG), a proton-doped silicon dioxide (SiO₂—H), etc. In the proton embodiment, the solid-state electrolyte layer 98 can also be an ultrathin layer of hexagonal boron nitride (hBN), graphene, or ZrO₂. In the proton embodiment, the gate layer 96 (as the proton reservoir) can be Pd (PdHₓ), Si—H, or HₓWO₃/metal bilayer, etc.

In embodiments in which O²⁻ anions (oxygen vacancies) are used as the mobile ion species to dope the channel layer 100, then the channel layer 100 can be composed of a channel material such as, for example, WOₓ, TiO₂₋ₓ, SmNiO₃, SrCoOₓ, Pr_{0.7}Ca_{0.3}MnO₃₋ₓ, etc. In the oxygen vacancy embodiment, the solid-state electrolyte layer 98 should be a good oxide-ion conductor, such as (ZrO₂)₁₋ₓ(Y₂O₃)ₓ (YSZ), stabilized-bismuth vanadate (Bi2V0.9Cu0.1O5.35, or HfO₂. In the oxygen vacancy embodiment, the gate layer 96 can be composed of a material as the channel layer 100.

In embodiments in which Li⁺ ions are used as the mobile ion species to dope the channel layer 100, then channel layer 100 can be composed of a channel material such as, for example, Li_(1-x)CoO2, Li_(x)WO3, LiₓTiO₂, LiₓFePO₄ and Li₄₊₃ₓTi₅O₁₂, etc.), or 2D materials, such as multilayer graphene or a conducting transition-metal dichalcogenide (TMD). In the Li⁺ion embodiment, the solid-state electrolyte layer 98 can be LiPON (lithium phosphorous oxynitride). In the Li⁺ ion embodiment, the solid-state electrolyte layer 98 can also be an ultrathin layer of hexagonal boron nitride (hBN), graphene, or ZrO₂. In the Li⁺ ion embodiment, the gate layer 96 can be Si or the same material as the channel, e.g., LiₓTiO₂, to reduce the open-circuit potential.

In any of the embodiments mentioned above, the components of the three-terminal memory element (e.g., MTJ structure 84—SOT channel layer 86, or MTJ structure 84—magentic oxide layer 85—SOT channel layer 86, or channel layer 96—solid-state electrolyte layer 98—channel layer 100), the three-terminal memory element is formed by deposition (e.g., sputtering, CVD, PECVD, or atomic layer deposition (ALD)) of blanket layers that provide the three-terminal memory element, followed by lithographic patterning in which an etch such as, for example, reactive ion etching or ion beam etching is used to removing portions of the blanket layers that are not protected by a patterned masking layer. After the etching, the patterned masking layer is removed providing the three-terminal memory element (e.g., MTJ structure 84—SOT channel layer 86, or MTJ structure 84—magentic oxide layer 85—SOT channel layer 86, or channel layer 96—solid-state electrolyte layer 98—channel layer 100). Note that during the etching process, a portion of the backside ILD layer 72 can be removed.

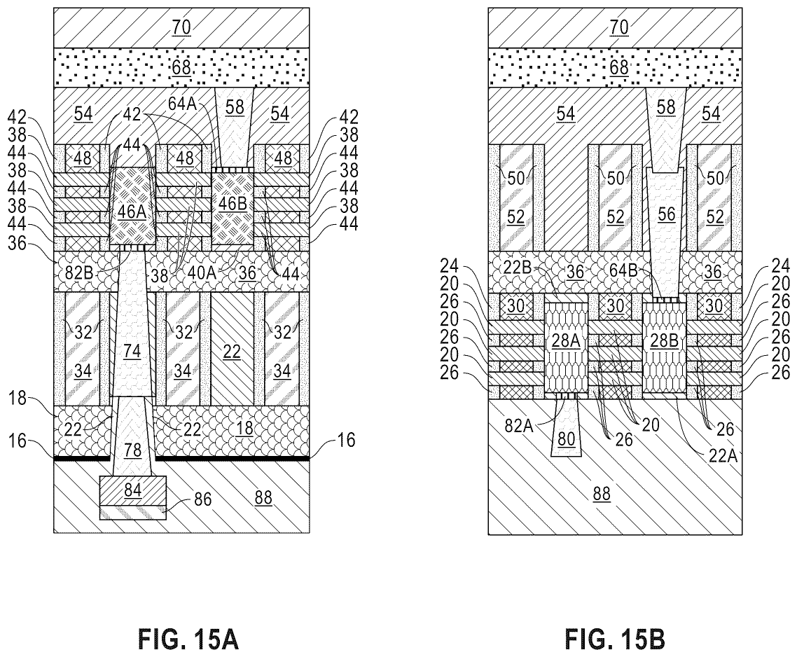

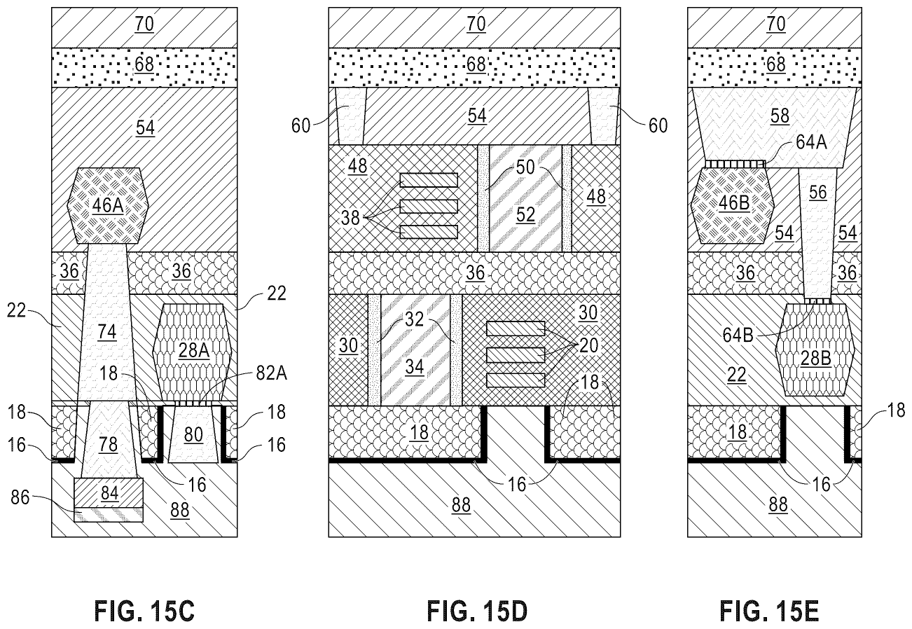

Next, additional backside ILD material is formed in the exemplary structure shown in FIGS. 14A-14E so as to provide the exemplary structure illustrated in FIGS. 15A-15E. The additional backside ILD material is formed adjacent to the three-terminal memory element (e.g., MTJ structure 84—SOT channel layer 86, or MTJ structure 84—magentic oxide layer 85—SOT channel layer 86, or channel layer 96—solid-state electrolyte layer 98—channel layer 100) and in contact with the backside ILD layer 72. Collectively, the backside ILD layer 72 and the additional backside ILD material provide a backside ILD structure 88 as illustrated in FIGS. 15A-15E. The additional backside ILD material can be compositionally the same as, or compositionally different from the ILD material that provides the backside ILD layer 72. The additional backside ILD material can be formed by a deposition process.

After forming the exemplary structure shown in FIGS. 15A-15E, a memory element contact structure 90 is formed in contact with the SOT channel layer 86 (or channel layer 100 for the ECRAM embodiment) and with the backside bottom source/drain contact structure 80 so as to provide the exemplary structure illustrated in FIGS. 16A-16E. The memory element contact structure 90 can be composed of at least a contact conductor material as mentioned above. The memory element contact structure 90 can also include a contact liner as mentioned above. The memory element contact structure 90 can be formed by a metallization process as mentioned above with the addition of utilizing a planarization process.

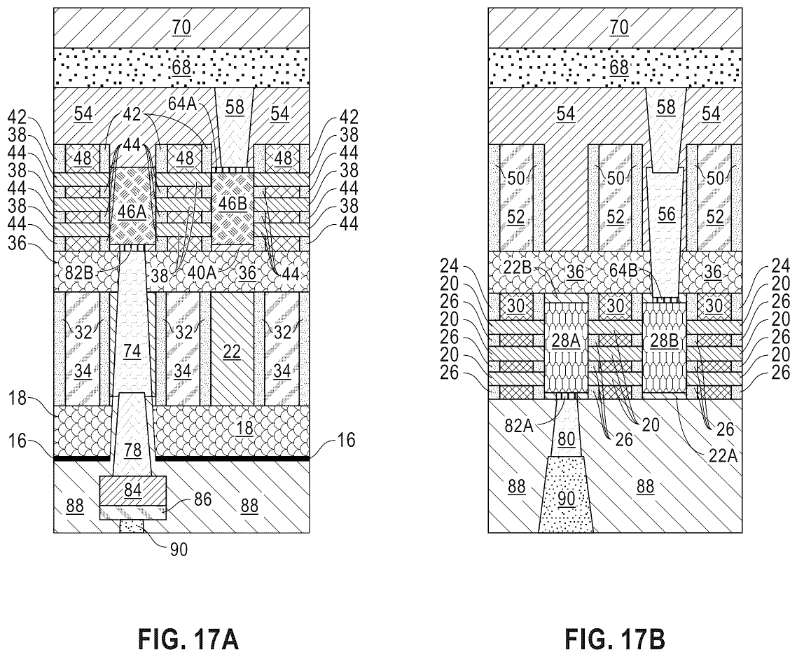

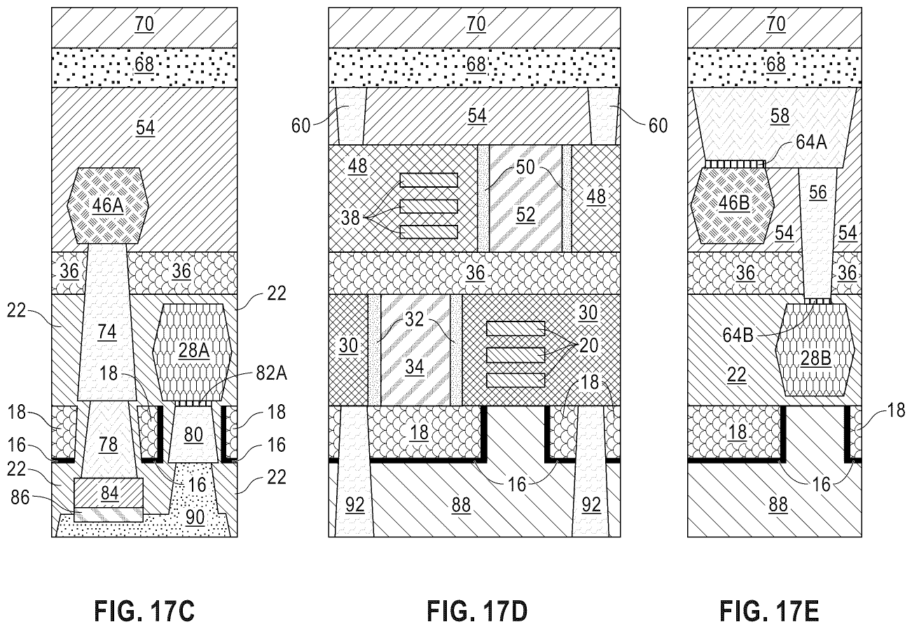

Next, and as is illustrated in FIGS. 17A-17E, a backside bottom gate contact structure 92 is formed to provide the exemplary structure illustrated in FIGS. 17A-17E. The backside bottom gate contact structure 92 can be composed of at least a contact conductor material as mentioned above. The backside bottom gate contact structure 92 can also include a contact liner as mentioned above. The backside bottom gate contact structure 92 can be formed by a metallization process as mentioned above with the addition of utilizing a planarization process.

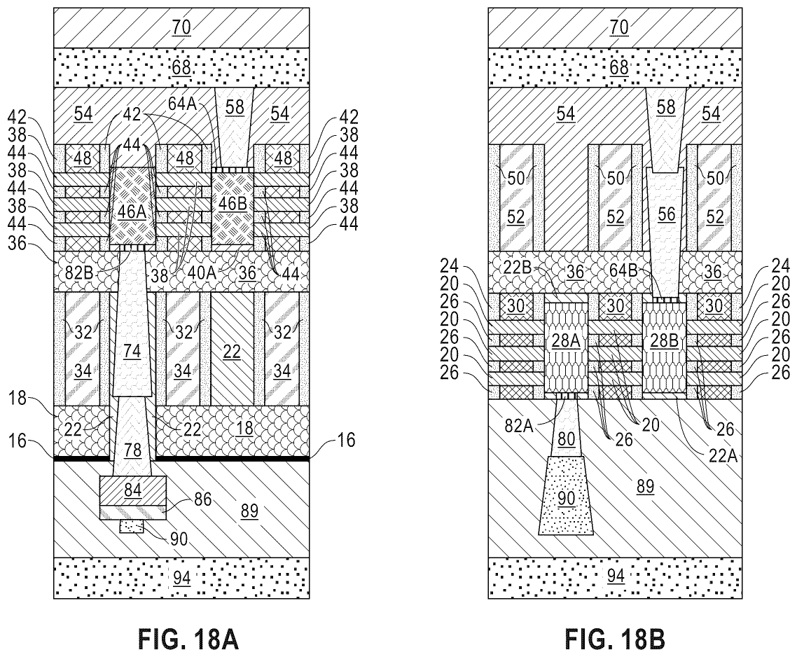

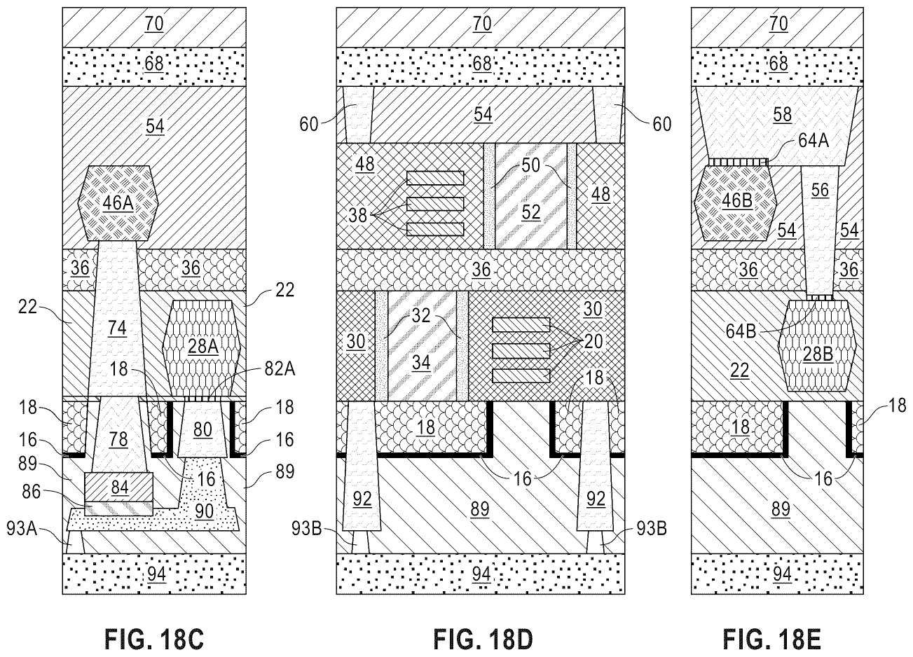

After providing the exemplary structure illustrated in FIGS. 17A-17E, a backside BEOL structure 94 is formed providing the exemplary structure shown in FIGS. 18A-18E; note FIGS. 18A-18E are equivalent to FIGS. 2A-2E. The formation of the backside BEOL structure 94 begins by forming additional backside ILD material on the backside ILD structure 88 and along a physically exposed horizontal surface of both the memory element contact structure 90 and the backside bottom gate contact structure 92. Collectively, the additional backside ILD layer and the backside ILD structure 88 provide a backside ILD multilayered structure 89 as illustrated in FIGS. 17A-17E. Backside contact vias are then formed utilizing a metallization process, followed by planarization. Backside contact vias are composed of an electrically conductive metal, electrically conductive metal alloy, or electrically conductive compounds as previous described in the present application. Backside contact vias may also contain metallic liners. Notably, a first backside contact via 93A is formed in contact with the memory element contact structure 90 and a second backside contact via 93B is formed in contact with the backside bottom gate contact structure 92.

Next, backside BEOL structure 94 is formed. The backside BEOL structure 94 is composed of an interconnect dielectric region having backside metal wiring embedded therein. The interconnect dielectric region includes one or more interconnect dielectric material layers. The interconnect dielectric material layers can be composed of low-k dielectric materials, such as SiCHO, SiCNO, SiNCHO, or at least one of the ILD materials mentioned above. The backside metal wiring can be in the form of metal lines, metal vias, a metal via/metal line combination or any combinations thereof. The backside metal wiring is composed of an electrically conductive metal, an electrically conductive metal alloy, or an electrically conductive compound as previously described herein and may also contain metallic liners. The backside BEOL structure 94 can be formed utilizing any well-known BEOL process including a damascene process or a subtractive metal etch process. The backside BEOL structure 94 can be configured to send power to the top and bottom transistors or alternatively used for backside signal or both.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a field effect transistor device having a frontside and a backside and comprising a top transistor stacked in a staggered configuration above a bottom transistor, wherein both the bottom transistor and the top transistor are located on the frontside of the field effect transistor device; and
a three-terminal memory element integrated with the field effect transistor device and present on the backside of the field effect transistor device, wherein the three-terminal memory element is positioned vertically and directly beneath one of the top transistor or the bottom transistor.

2. The semiconductor device of claim 1, wherein the three-terminal memory element comprises a spin-orbit torque magnetoresistive random access memory comprising a magnetic tunnel junction structure located directly on a spin-orbit torque channel layer.

3. The semiconductor device of claim 1, wherein the three-terminal memory element comprises a spin-orbit torque magnetoresistive random access memory comprising a magnetic oxide layer positioned between a magnetic tunnel junction structure and a spin-orbit torque channel layer.

4. The semiconductor device of claim 1, wherein the three-terminal memory element comprises an electrochemical random access memory comprising a solid-state electrolyte layer positioned between a gate layer and a channel layer.

5. The semiconductor device of claim 1, further comprising backside contact structures electrically connecting the three-terminal memory element to the bottom transistor and the top transistor of the field effect transistor device, wherein at least one of the backside contact structures comprises a metal silicide layer in direct contact with a source/drain region of either the top transistor or the bottom transistor.

6. The semiconductor device of claim 1, wherein the three-terminal memory element is positioned vertically and directly beneath the top transistor, and the three-terminal memory element has an uppermost layer electrically connected to a top transistor first source/drain region and a bottommost layer electrically connected to both a bottom first source/drain region and a backside back-end-of-line structure that is located beneath the three-terminal memory element, wherein the top transistor comprises a top transistor second source/drain region electrically connected to both a bottom transistor second source/drain region and a frontside back-end-of-line structure that is positioned above the top transistor.

7. The semiconductor device of claim 6, wherein the bottom transistor comprises a bottom transistor gate electrode electrically connected to the backside back-end-of-line structure and the top transistor comprises a top transistor gate electrode electrically connected to the frontside back-end-of-line structure.

8. The semiconductor device of claim 1, wherein the three-terminal memory element is positioned vertically and directly beneath the bottom transistor, and the three-terminal memory element has an uppermost layer electrically connected to a bottom transistor first source/drain region and a bottommost layer electrically connected to both a top transistor first source/drain region and a backside back-end-of-line structure that is located beneath the three-terminal memory element, wherein the top transistor comprises a top transistor second source/drain region electrically connected to both a bottom transistor second source/drain region and a frontside back-end-of-line structure that is positioned above the top transistor.

9. The semiconductor device of claim 8, wherein the bottom transistor comprises a bottom transistor gate electrode electrically connected to the backside back-end-of-line structure and the top transistor comprises a top transistor gate electrode electrically connected to the frontside back-end-of-line structure.

10. The semiconductor device of claim 1, wherein the top transistor and the bottom transistor are of a same polarity.

11. The semiconductor device of claim 1, wherein the top transistor and the bottom transistor are of a different polarity.

12. The semiconductor device of claim 1, further comprising a bonding dielectric layer separating the top transistor from the bottom transistor.

13. A semiconductor device comprising:
a field effect transistor device having a frontside and a backside and comprising a top transistor stacked in a staggered configuration above a bottom transistor, wherein both the bottom transistor and the top transistor are located on the frontside of the field effect transistor device; and
a three-terminal memory element integrated with the field effect transistor device and present on the backside of the field effect transistor device, wherein the three-terminal memory element is positioned vertically and directly beneath the top transistor, and the three-terminal memory element has an uppermost layer electrically connected to a top transistor first source/drain region and a bottommost layer electrically connected to both a bottom transistor first source/drain region and a backside back-end-of-line structure that is located beneath the three-terminal memory element, wherein the top transistor comprises a top transistor second source/drain region electrically connected to both a bottom transistor second source/drain region and a frontside back-end-of-line structure that is positioned above the top transistor and wherein the bottom transistor comprises a bottom transistor gate electrode electrically connected to the backside back-end-of-line structure and the top transistor comprises a top transistor gate electrode electrically connected to the frontside back-end-of-line structure.

14. The semiconductor device of claim 13, wherein the three-terminal memory element comprises a spin-orbit torque magnetoresistive random access memory comprising a magnetic tunnel junction structure located directly on a spin-orbit torque channel layer.

15. The semiconductor device of claim 13 wherein the three-terminal memory element comprises a spin-orbit torque magnetoresistive random access memory comprising a magnetic oxide layer positioned between a magnetic tunnel junction structure and a spin-orbit memory channel layer.

16. The semiconductor device of claim 13, wherein the three-terminal memory element comprises an electrochemical random access memory comprising a solid-state electrolyte layer positioned between a gate layer and a channel layer.

17. A semiconductor device comprising:
a field effect transistor device having a frontside and a backside and comprising a top transistor stacked in a staggered configuration above a bottom transistor, wherein both the bottom transistor and the top transistor are located on the frontside of the field effect transistor device; and
a three-terminal memory element integrated with the field effect transistor device and present on the backside of the field effect transistor device, wherein the three-terminal memory element is positioned vertically and directly beneath the bottom transistor, and the three-terminal memory element has an uppermost layer electrically connected to a bottom transistor first source/drain region and a bottommost layer electrically connected to both a top transistor first source/drain region and a backside back-end-of-line structure that is located beneath the three-terminal memory element, wherein the top transistor comprises a top transistor second source/drain region electrically connected to both a bottom transistor second source/drain region and a frontside back-end-of-line structure that is positioned above the top transistor, and wherein the bottom transistor comprises a bottom transistor gate electrode electrically connected to the backside back-end-of-line structure and the top transistor comprises a top transistor gate electrode electrically connected to the frontside back-end-of-line structure.

18. The semiconductor device of claim 17, wherein the three-terminal memory element comprises a spin-orbit torque magnetoresistive random access memory comprising a magnetic tunnel junction structure located directly on a spin-orbit torque channel layer.

19. The semiconductor device of claim 17 wherein the three-terminal memory element comprises a spin-orbit torque magnetoresistive random access memory comprising a magnetic oxide layer positioned between a magnetic tunnel junction structure and a spin-orbit torque channel layer.

20. The semiconductor device of claim 17, wherein the three-terminal memory element comprises an electrochemical random access memory comprising a solid-state electrolyte layer positioned between a gate layer and a channel layer.
